(19) United States
(12) Patent Application Publication
(10) Pub. No.: US 2009/0057822 A1
(43) Pub. Date: Mar. 5, 2009

(54) SEMICONDUCTOR COMPONENT AND METHOD OF MANUFACTURE

(76) Inventors: Yenting Wen, Chandler, AZ (US); Helmut Schweiss, Phoenix, AZ (US)

Correspondence Address: SEMICONDUCTOR COMPONENTS INDUSTRIES, LLC;INTELLECTUAL PROPERTY DEPT. - A700, 5005 E. MCDOWELL ROAD, P.O.BOX 62890, PHOENIX, AZ, 85082, US

(21) Appl. No.: 11/850,153

(22) Filed: Sep. 5, 2007

(51) Int. Cl. H01L 29/00; H01L 21/00

(52) U.S. Cl. 257/531; 438/123; 257/E29.001

(57) ABSTRACT

A semiconductor component that includes a leadframe, a discrete passive circuit element, and an active circuit element. The discrete passive circuit element such as, for example, a discrete ferrite core inductor, is mounted either laterally or vertically adjacent to the leadframe. A semiconductor chip is attached to the discrete ferrite core inductor. Bond pads on the semiconductor chip may be electrically coupled to leads from the leadframe or to the discrete ferrite core inductor by wire bonds. The leadframe, discrete ferrite core inductor, semiconductor chip, and wire bonds are protected by an encapsulant such as a mold compound. Other passive circuit elements may be mounted to the discrete ferrite core inductor before encapsulation in the mold compound.

### TECHNICAL FIELD

The present invention relates, in general, to a semiconductor component and, more particularly, to a semiconductor component comprising active and passive circuit elements.

### BACKGROUND

Electronic circuits are used in a variety of portable and non-portable applications including automotive, telecommunications, medical, aeronautical, maritime, computing, gaming, etc. Electronic circuit manufacturers constantly strive to decrease the size and manufacturing costs of these circuits while increasing their functionality and performance. Typically electronic circuits are comprised of active and passive circuit elements mounted on a printed circuit board. Although these circuit boards incorporate interconnect structures that allow the active and passive circuit elements to communicate with each other, they increase the cost of manufacturing electronic circuits and may decrease their performance. Another approach for increasing the functionality and performance of electronic circuits has been to integrate various circuit elements into a single semiconductor substrate. A drawback with this approach is that passive circuit elements such as inductors and capacitors consume a large area of the semiconductor substrate. Thus, they increase the cost of manufacturing the electronic circuit.

Accordingly, it would be advantageous to have a semiconductor component that comprises active and passive circuit elements and a method for manufacturing the semiconductor component that is cost and time efficient.

### BRIEF DESCRIPTION OF THE DRAWINGS

The present invention will be better understood from a reading of the following detailed description, taken in conjunction with the accompanying drawing figures, in which like reference characters designate like elements and in which:

FIG. 1 is a top view of a leadframe used in the manufacture of a semiconductor component in accordance with an embodiment of the present invention;

FIG. 2 is a cross-sectional view of the leadframe of FIG. 1 taken along section line 2-2 of FIG. 1;

FIG. 3 is a cross-sectional view of the leadframe of FIG. 2 after thinning in accordance with an embodiment of the present invention;

FIG. 4 is a cross-sectional view of a plurality of semiconductor components during manufacture using the leadframe of FIG. 3 in accordance with an embodiment of the present invention;

FIG. 5 is a cross-sectional view of the plurality of semiconductor components of FIG. 4 at a later stage of manufacture;

FIG. 6 is a top view of the plurality of semiconductor components of FIG. 5 of FIG. 4 at a later stage of manufacture;

FIG. 7 is a cross-sectional view of a singulated semiconductor component in accordance with an embodiment of the present invention;

FIG. 8 is an isometric view of the singulated semiconductor component of FIG. 7;

FIG. 9 is a cross-sectional view of the leadframe of FIG. 2 after thinning in accordance with another embodiment of the present invention;

FIG. 10 is a cross-sectional view of a plurality of semiconductor components during manufacture using the leadframe of FIG. 9;

FIG. 11 is a cross-sectional view of another singulated semiconductor component in accordance with another embodiment of the present invention;

FIG. 12 is an isometric view of the singulated semiconductor component of FIG. 11;

FIG. 13 is a top view of a leadframe used in the manufacture of another semiconductor component in accordance with another embodiment of the present invention;

FIG. 14 is a cross-sectional view of the leadframe of FIG. 13 taken along section line 14-14 of FIG. 13;

FIG. 15 is a cross-sectional view of a plurality of semiconductor components during manufacture using the leadframe of FIG. 14;

FIG. 16 is a cross-sectional view of a singulated semiconductor component in accordance with another embodiment of the present invention;

FIG. 17 is an isometric view of the singulated semiconductor component of FIG. 16;

FIG. 18 is a top view of a leadframe used in the manufacture of another semiconductor component in accordance with another embodiment of the present invention;

FIG. 19 is a cross-sectional view of the leadframe of FIG. 18 taken along section line 19-19 of FIG. 18;

FIG. 20 is a cross-sectional view of the leadframe of FIG. 19 after thinning in accordance with another embodiment of the present invention;

FIG. 21 is a top view of the plurality of semiconductor components during manufacture using the leadframe of FIG. 20 in accordance with another embodiment of the present invention;

FIG. 22 is an isometric view of a singulated semiconductor component of FIG. 21;

FIG. 23 is a top view of a leadframe used in the manufacture of another semiconductor component in accordance with another embodiment of the present invention;

FIG. 24 is a cross-sectional view of the leadframe of FIG. 23 taken along section line 24-24 of FIG. 23;

FIG. 25 is a cross-sectional view of the leadframe of FIG. 23 taken along section line 25-25 of FIG. 23;

FIG. 26 is a cross-sectional view of the leadframe of FIG. 25 after thinning in accordance with another embodiment of the present invention;

FIG. 27 is a top view of the plurality of semiconductor components during manufacture using the leadframe of FIG. 26 in accordance with another embodiment of the present invention;

FIG. 28 is a cross-sectional view of a singulated semiconductor component in accordance with an embodiment of the present invention;

FIG. 29 is a top view of a leadframe used in the manufacture of another semiconductor component in accordance with another embodiment of the present invention;

FIG. 30 is a cross-sectional view of the leadframe of FIG. 29 taken along section line 30-30 of FIG. 29;

FIG. 31 is a cross-sectional view of the leadframe of FIG. 29 taken along section line 31-31 of FIG. 30;

FIG. 32 is a cross-sectional view of the leadframe shown in FIG. 31 after thinning in accordance with another embodiment of the present invention;

FIG. 33 is a top view of the plurality of semiconductor components during manufacture using the leadframe of FIG. 32 in accordance with another embodiment of the present invention;

FIG. 34 is an isometric view of the semiconductor component of FIG. 33 after encapsulation in a mold compound and singulation into an individual semiconductor component;

FIG. 35 is a top view of a plurality of semiconductor components during manufacture in accordance with another embodiment of the present invention;

FIG. 36 is an isometric view of another singulated semiconductor component in accordance with another embodiment of the present invention;

FIG. 37 is a top view of a plurality of semiconductor components during manufacture in accordance with another embodiment of the present invention;

FIG. 38 is an isometric view of a singulated semiconductor component of FIG. 37;

FIGS. 39 is an isometric view of another singulated semiconductor component in accordance with another embodiment of the present invention; and

FIG. 40 is an isometric view of another singulated semiconductor component in accordance with another embodiment of the present invention.

### DETAILED DESCRIPTION

Generally the present invention provides a semiconductor component comprising a discrete passive device, a semiconductor chip, and a leadframe and a method for manufacturing the semiconductor component. A discrete passive device is also referred to as a discrete passive circuit element. In accordance with some embodiments, the semiconductor components comprise a discrete passive circuit element mounted to a leadframe and a semiconductor chip mounted to the discrete passive circuit element. The discrete passive circuit element may be bonded to the leadframe using solder and the semiconductor chip may be bonded to the discrete passive circuit element using a die attach material. Bond pads formed on the semiconductor chip are bonded to the leadframe using wire bonds. By way of example, the discrete passive circuit element is a ferrite core inductor. An advantage of using a discrete ferrite core inductor is that the inductance value of the inductor may range from at least about 50 nanoHenrys (nH) to more than 1,000 nH, which is sufficiently large for high power applications such as, for example, in Direct Current to Direct Current (“DC-DC”) power conversion circuits. Although integrated passive inductors, i.e., integrated passive devices that include one or more inductors, are suitable for use in low power high frequency applications, they are unsuitable for use in high power applications because inductance values of at least about 50 nH are used. Integrated passive inductors with inductance values of this size would occupy too much space to be practical. Likewise, integrated passive resistors and capacitors are impractical to use because of their sizes.

Another advantage of semiconductor components in accordance with embodiments of the present invention is that the discrete passive circuit elements may facilitate removal of heat from the semiconductor chips thereby improving the thermal performance of the semiconductor components.

Another advantage of semiconductor components in accordance with embodiments of the present invention is that they have a lower profile than semiconductor components manufactured using printed circuit board materials.

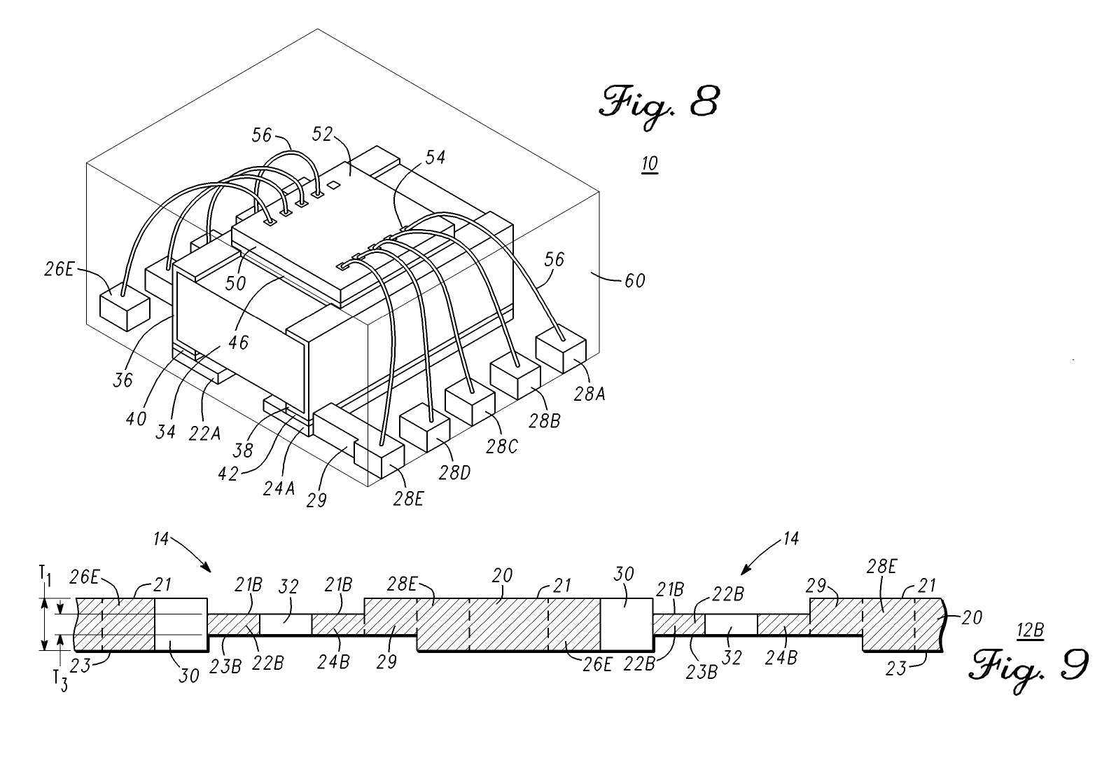

FIG. 1 is a top view of a leadframe 12 having opposing surfaces 21 and 23 used in the manufacture of a semiconductor component 10 (shown in FIGS. 7 and 8) in accordance with an embodiment of the present invention. Surface 21 is also referred to as a top surface and surface 23 (shown in FIG. 2) is also referred to as a bottom surface. Leadframe 12 comprises a plurality of semiconductor component sections 14 from which a semiconductor component may be manufactured. It should be noted that a leadframe typically comprises a plurality of semiconductor component sections arranged in an M×N peripheral array, where M is the number of rows in the array and N is the number of columns in the array. The numbers of rows and columns is not a limitation of the present invention. What is shown in FIG. 1 is a 1×2 array of semiconductor component sections wherein the row has opposing rails 16 and 18 that are coupled to each other by tie-bars 20. Preferably, tie-bars 20 are substantially perpendicular to opposing rails 16 and 18. A semiconductor component section 14 is bounded by opposing rails 16 and 18 and by adjacent tie-bars 20. In addition, opposing rails 16 and 18 may be coupled to each other by conductive strips 22 and 24. Thus, semiconductor component sections 14 may also include conductive strips 22 and 24. Conductive strips 22 and 24 are spaced apart by openings 32.

In accordance with some embodiments, a semiconductor component section may comprise leadframe leads 26 that extend from a tie-bar 20 toward conductive strip 22 and leadframe leads 28 that extend from an adjacent tie-bar 20 toward conductive strip 24. More particularly, leadframe leads 26A, 26B, 26C, 26D, and 26E extend from one side of tie-bars 20 into an opening 30 toward conductive strips 22 and leadframe leads 28A, 28B, 28C, 28D, and 28E extend from the opposing side of adjacent tie-bars 20 toward conductive strips 24. It should be noted that one of leadframe leads 26, e.g., leadframe lead 26A, is longer than leadframe leads 26B-26E. The longer portion of leadframe lead 26A also referred to as a leadframe lead extension 27, connects leadframe lead 26A to conductive strip 22. Similarly, one of leadframe leads 28, e.g., leadframe lead 28E, is longer than leadframe leads 28A-28D. The longer portion of leadframe lead 28E, also referred to as a leadframe lead extension 29, connects leadframe lead 28E to conductive strip 24. Although leadframe lead extensions 27 and 29 are shown as extending from the leadframe leads nearest rails 16 and 18 respectively, e.g., extending from leadframe leads 26A and 28E, the leadframe leads 26 and 28 from which leadframe lead extensions 27 and 29 extend is not a limitation of the present invention. For example, leadframe leads 27 and 29 may extend from leadframe leads 26C and 28C or form leadframe leads 26B and 28D, etc. Leadframe leads 26 and 28 may be referred to as leadframe fingers and extensions 27 and 29 may be referred to as leadframe lead extensions, leadframe lead extenders, leadframe finger extensions, or leadframe finger extenders.

Suitable materials for leadframe 12 include thermally and electrically conductive materials such as, for example, copper, a copper alloy, aluminum, an aluminum alloy, silver, a silver alloy, or the like. In accordance with some embodiments, leadframe 12 has a thickness ranging from about 50 micrometers (“μm”) to about 1,000 μm. By way of example, leadframe 12 has a thickness of about 200 μm. Techniques for manufacturing leadframes are known to those skilled in the art. The technique for manufacturing leadframe 12, the number of leadframe leads, the number of semiconductor component sections, and the thickness of leadframe 12 are not limitations of the present invention.

FIG. 2 is a cross-sectional view of leadframe 12 taken along section line 2-2 of FIG. 1. FIG. 2 illustrates opposing surfaces 21 and 23, leadframe leads 26E spaced apart from conductive strips 22 by openings 30, and conductive strips 24 spaced apart from conductive strips 22 by openings 32. In addition, FIG. 2 illustrates leadframe leads 26 and 28 extending from opposing sides of adjacent tie-bars 20. Extensions 29 separate leadframe leads 28E that are extending from tie-bars 20 from conductive strips 24. Although not shown in the cross-sectional view of FIG. 2, extensions 27 separate leadframe leads 26A that are extending from tie-bars 20 from conductive strips 22. For the sake of clarity, vertical broken lines are used to distinguish leadframe leads 26E and 28E, tie-bars 20, conductive strips 24, and extensions 29.

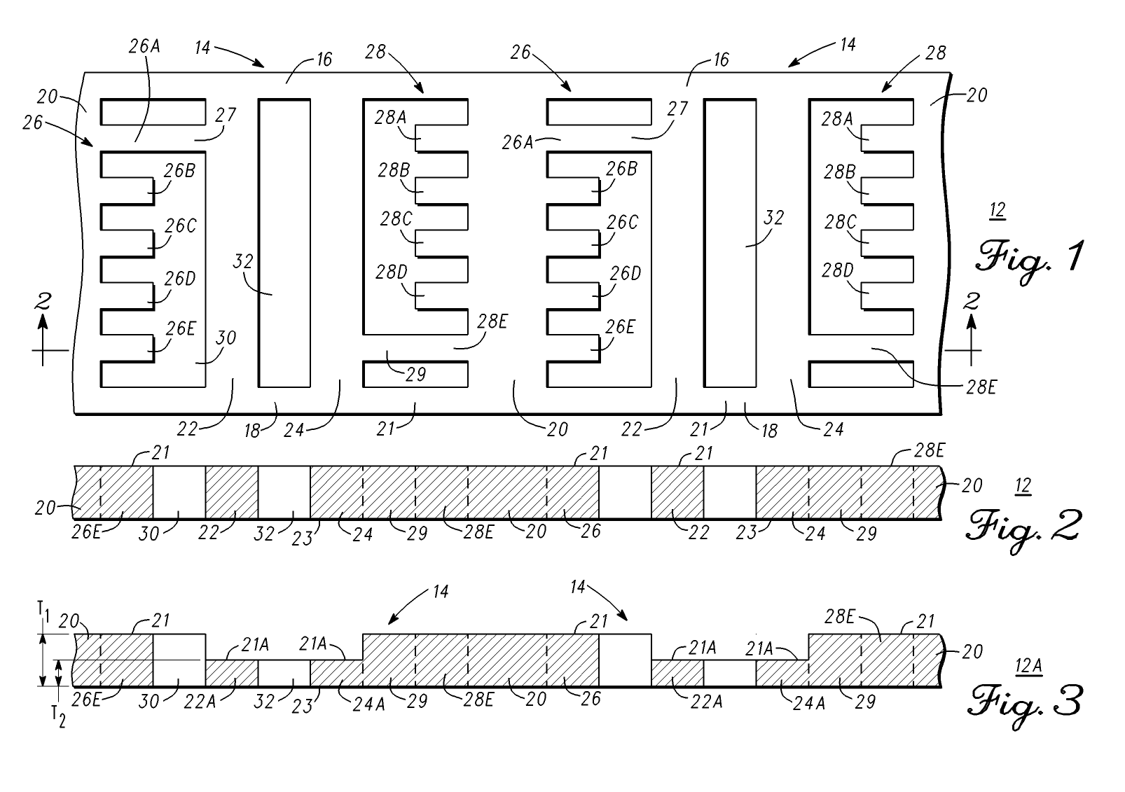

FIG. 3 is a cross-sectional view of leadframe 12 shown in FIG. 2 after conductive strips 22 and 24 have been thinned. In accordance with one embodiment, conductive strips 22 and 24 are thinned from surface 21 into leadframe 12 to have a thickness of about one-half of their thicknesses before thinning. For example, when leadframe 12 has a thickness, T₁, of about 200 μm, conductive strips 22 and 24 are thinned from about 200 μm to a thickness, T₂, of about 100 μm. The thinned conductive strips are identified by reference characters 22A and 24A, their top surfaces are identified by reference character 21A, and the leadframe is identified by reference character 12A. It should be noted that the thinning from top surface 21 preferably does not remove leadframe material from bottom surface 23. Techniques for thinning leadframe 12 include wet chemical etching (e.g., a hydrochloric acid etch), grinding, stamping, or the like. The method for thinning leadframe 12 and the final thickness of conductive strips 22 and 24 are not limitations of the present invention. For example, thinned conductive strips 22A and 24A may have a thickness of less than about 200 μm, less than about 100 μm, less than about 50 μm, etc.

FIG. 4 is a cross-sectional view of the plurality of semiconductor component sectons 14 of FIG. 3 further along in manufacture. A discrete passive component 34 is mounted to each semiconductor component section 14. In accordance with some embodiments, discrete passive component 34 is a ferrite core inductor having contact terminals 36 and 38 and a mating surface 45. Contact terminals 36 and 38 may be referred to as terminals or contacts. In accordance with some embodiments, contact terminals 36 and 38 are comprised of tin and lead. Contact terminal 36 is coupled to conductive strip 22A by solder 40 and contact terminal 38 is coupled to conductive strip 24A by solder 42. Thus, contact terminals 36 and 38 are soldered to conductive strips 22A and 24A, respectively, of leadframe 12. Preferably, solder 40 and 42 is a lead-free solder. Alternatively, contact terminals 36 and 38 may be coupled to conductive strips 22A and 24A using a conductive epoxy. Although solder 40 and 42 are shown as being between conductive strips 22A and 24A, it should be noted that solder 40 and 42 may extend vertically along contact terminals 36 and 38, respectively.

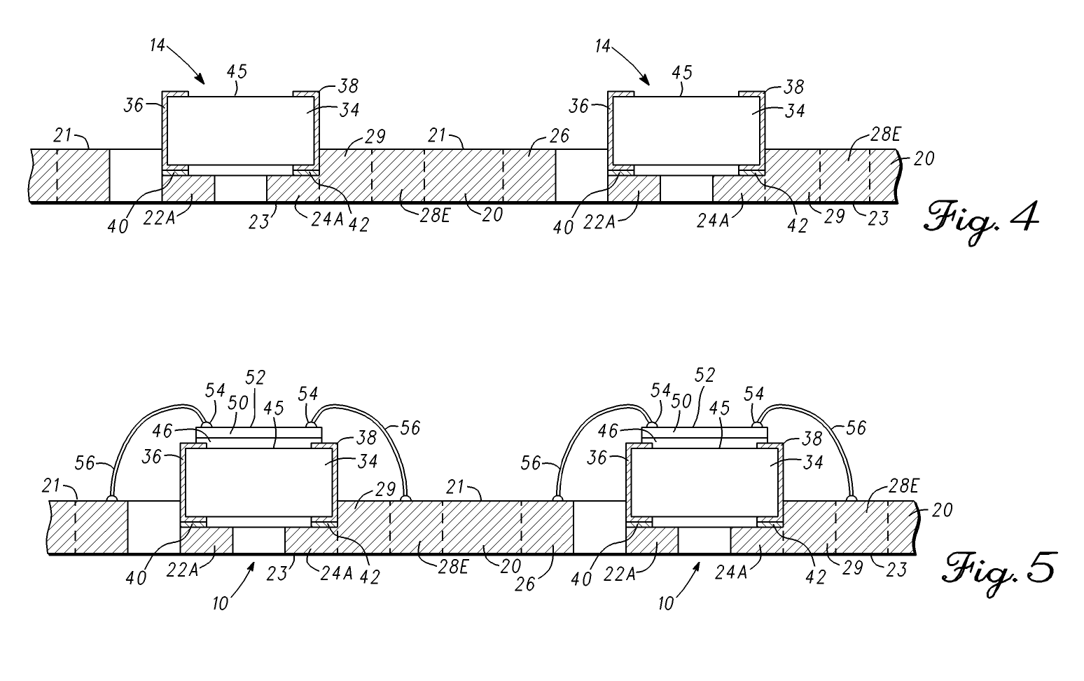

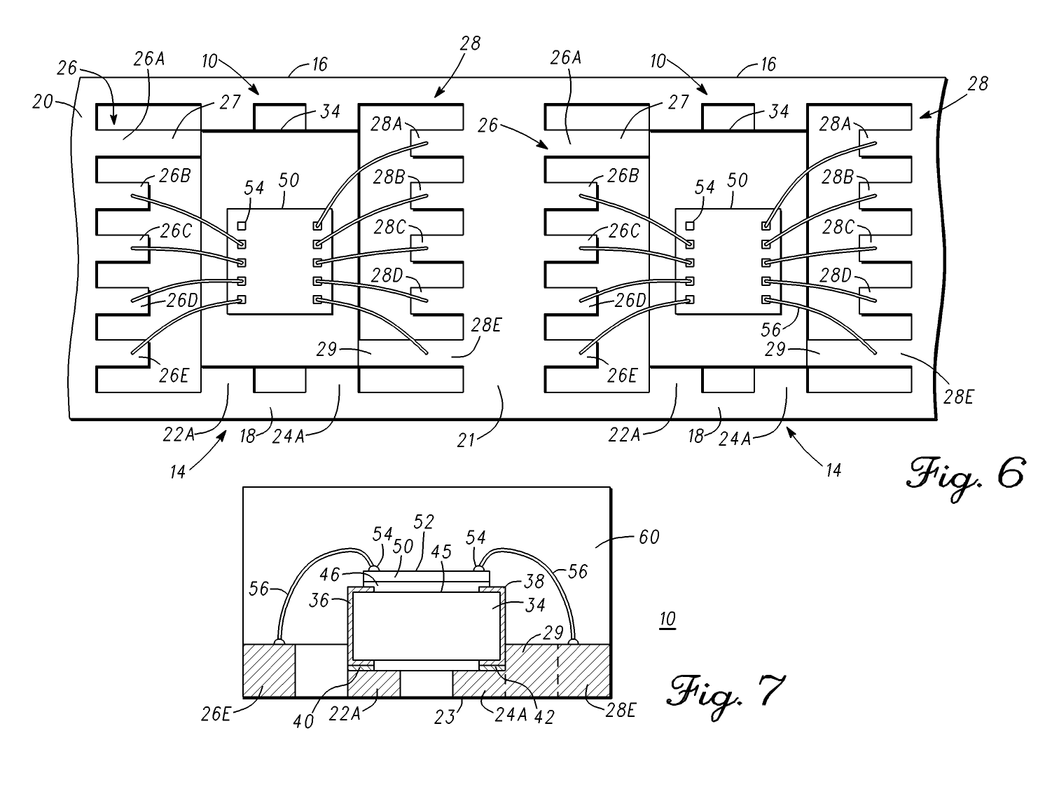

FIG. 5 is a cross-sectional view of the plurality of semiconductor component regions 14 of FIG. 4 further along in manufacture. A die attach material 46 is disposed on mating surfaces 45 and portions of contact terminals 36 and 38 of ferrite core inductors 34. In accordance with some embodiments, die attach material 46 is thermally conductive and electrically nonconductive. Suitable die attach materials include an electrically non-conductive epoxy, a die attach film, or the like. A semiconductor chip 50 is mounted in die attach material 46 and die attach material 46 is cured. Semiconductor chip 50 in combination with ferrite core inductor 34 and leadframe 12A form a portion of a semiconductor component 10.

Semiconductor chip 50 has a surface 52 on which a plurality of bond pads 54 are formed. Semiconductor chip 50 is also referred to as a semiconductor die and may contain active devices, passive circuit elements, or a combination of active and passive circuit elements. The active devices may include field effect transistors, bipolar junction transistors, insulated gate bipolar transistors, or the like and the passive circuit elements may include discrete resistors, discrete capacitors, discrete inductors, or the like. For example, the discrete capacitors may be chip capacitors, the discrete resistors may be chip resistors, and the discrete inductor may be chip inductors. The types of devices formed in semiconductor chips 50 are not limitations of the present invention. What's more, the types of circuits formed from the devices is not a limitation of the present invention. Bond pads 54 are electrically coupled to corresponding leadframe leads 26 and 28 using, for example, wire bonds 56, wedge bonds, ball bonds, etc. Wire bonds are also referred to as bonding wires. The means for electrically coupling bond pads 54 to the corresponding leadframe leads 26 is not a limitation of the present invention.

Although solder 40 and 42 are shown as being between conductive strips 22A and 24A, it should be noted that solder 40 and 42 may extend vertically along contact terminals 36 and 38, respectively.

FIG. 6 is a top view of the plurality of semiconductor components 10 of FIG. 5. What is shown in FIG. 6 are discrete ferrite core inductors 34 coupled to corresponding semiconductor component sections 14. A semiconductor chip 50 is mounted to each ferrite core inductor 34 and bond pads 54 are electrically coupled to the corresponding leadframe leads 26 and 28. In some embodiments more than one bond pad 54 may be electrically coupled to a leadframe lead 26 or to a leadframe lead 28.

Leadframe 12 on which ferrite core inductors 34 and semiconductor chips 50 are mounted is placed in a mold assembly (not shown). An encapsulating material such as, for example, a mold compound 60 (shown in FIG. 7), is injected into the mold assembly and cured. Semiconductor component sections 14 are then singulated from the leadframe assembly.

FIG. 7 illustrates a semiconductor component 10 after encapsulation in mold compound 60 and singulation into individual semiconductor components. In accordance with this embodiment, lead frame leads 26 and 28, and thinned conductive strips 22A and 24A are exposed. Although solder 40 and 42 are shown as being between conductive strips 22A and 24A, it should be noted that solder 40 and 42 may extend vertically along contact terminals 36 and 38, respectively.

FIG. 8 is an isometric view of semiconductor component 10 of FIG. 7. FIG. 8 illustrates inductor 34 mounted on thinned conductive strips 22A and 24A, semiconductor chip 50 attached to discrete inductor 34 by a die attach material 46, and wire bonds 56 coupling leadframe leads 26 and 28 to bond pads 54. Discrete inductor 34, semiconductor chip 50, portions of leadframe leads 26 and 28 and portions of thinned conductive strips 22A and 24A are protected by mold compound 60. Although solder 40 and 42 are shown as being between conductive strips 22A and 24A, it should be noted that solder 40 and 42 may extend vertically along contact terminals 36 and 38, respectively.

FIG. 9 is a cross-sectional view of a leadframe 12B for use in manufacturing a semiconductor component 100 (shown in FIG. 11) in accordance with another embodiment of the present invention. It should be noted that the description of leadframe 12 in FIGS. 1 and 2 applies to leadframe 12B. Thus, the description of FIG. 9 continues from that of FIG. 2. FIG. 9 illustrates leadframe 12B after conductive strips 22 and 24 have been thinned from top surfaces 21 and from bottom surfaces 23. Accordingly, conductive strips 22 and 24 are etched from surfaces 21 and 23 into leadframe 12. In addition, extensions 27 and 29 are thinned from bottom surfaces 23. In accordance with one embodiment, conductive strips 22 and 24 are thinned to have a thickness of about one-half the thickness of leadframe 12. For example, when leadframe 12 has a thickness, T₁, of about 200 μm, conductive strips 22 and 24 are thinned by about 50 μm from their top and bottom surfaces. Thus, the thickness T₃ of conductive strips 22 and 24 is about 100 μm. Extensions 27 and 29 are thinned by about 50 μm from their bottoms surfaces. The thinned conductive strips are identified by reference characters 22B and 24B, their top surfaces are identified by reference character 21B, their bottom surfaces are identified by reference character 23B, and the leadframe is identified by reference character 12B. Techniques for thinning leadframe 12 include wet chemical etching (e.g., a hydrochloric acid etch), grinding, stamping, or the like. The method for thinning leadframe 12 and the final thickness of conductive strips 22 and 24 are not limitations of the present invention. For example, thinned conductive strips 22B and 24B may have a thickness of less than about 200 μm, less than about 100 μm, less than about 50 μm, etc. The method for thinning leadframe 12 is not a limitation of the present invention.

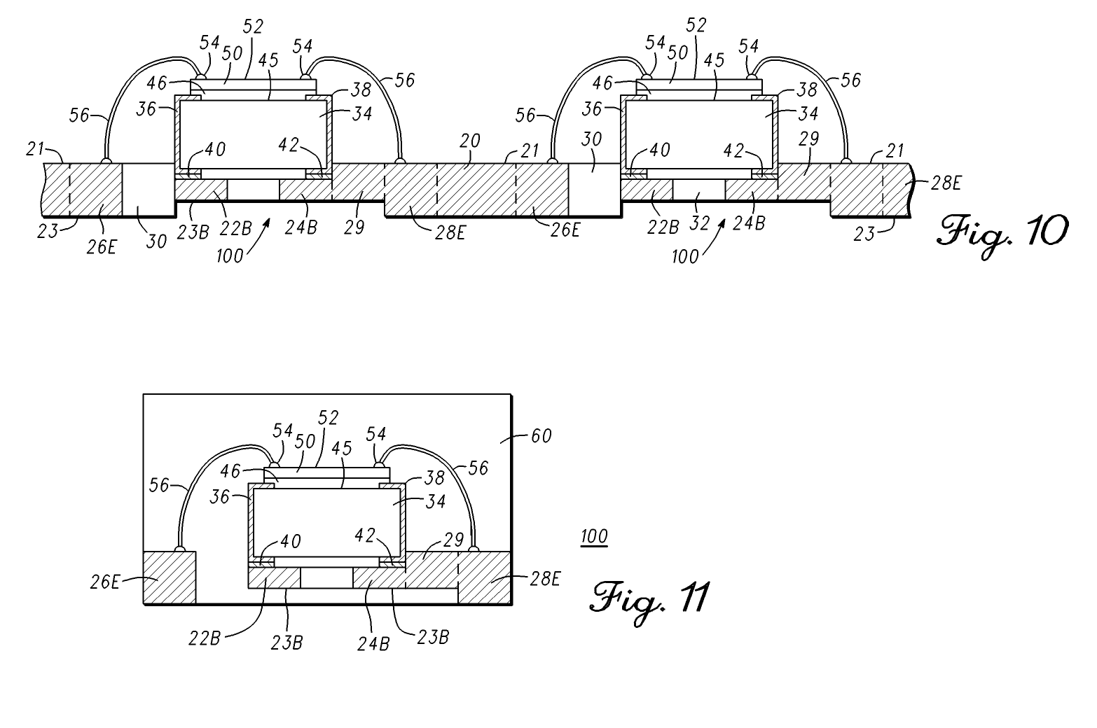

FIG. 10 is a cross-sectional view of semiconductor components 100 during manufacture. What is shown in FIG. 10 are discrete passive components 34 mounted to each semiconductor component section 14. In accordance with some embodiments, discrete passive component 34 is a ferrite core inductor having contact terminals 36 and 38 and mating surface 45. Terminal 36 is coupled to thinned conductive strip 22B by solder 40 and terminal 38 is coupled to thinned conductive strip 24B by solder 42. Although solder 40 and 42 are shown as being between conductive strips 22B and 24B it should be noted that solder 40 and 42 may extend vertically along contact terminals 36 and 38, respectively.

A die attach material 46 is disposed on mating surfaces 45 and portions of terminals 36 and 38 of ferrite core inductors 34. In accordance with some embodiments, die attach material 46 is thermally conductive and electrically nonconductive. Suitable die attach materials include an electrically non-conductive epoxy, a die attach film, or the like. A semiconductor chip 50 is mounted in die attach material 46 and die attach material 46 is cured.

Preferably, each semiconductor chip 50 has a surface 52 on which a plurality of bond pads 54 are formed. Bond pads 54 are electrically coupled to corresponding leadframe leads 26 and 28 using, for example, wire bonds 56, wedge bonds, ball bonds, etc. Wire bonds 56 are also referred to as bonding wires. The means for electrically coupling bond pads 54 to the corresponding leadframe leads 26 is not a limitation of the present invention. Discrete passive circuit element 34, semiconductor chips 50, bond pads 54, and wire bonds 56 have been discussed with reference to FIGS. 4 and 5.

FIG. 11 illustrates a singulated semiconductor component 100 after encapsulation in a mold compound 60 and singulation. Although solder 40 and 42 are shown as being between conductive strips 22A and 24A, it should be noted that solder 40 and 42 may extend vertically along contact terminals 36 and 38, respectively.

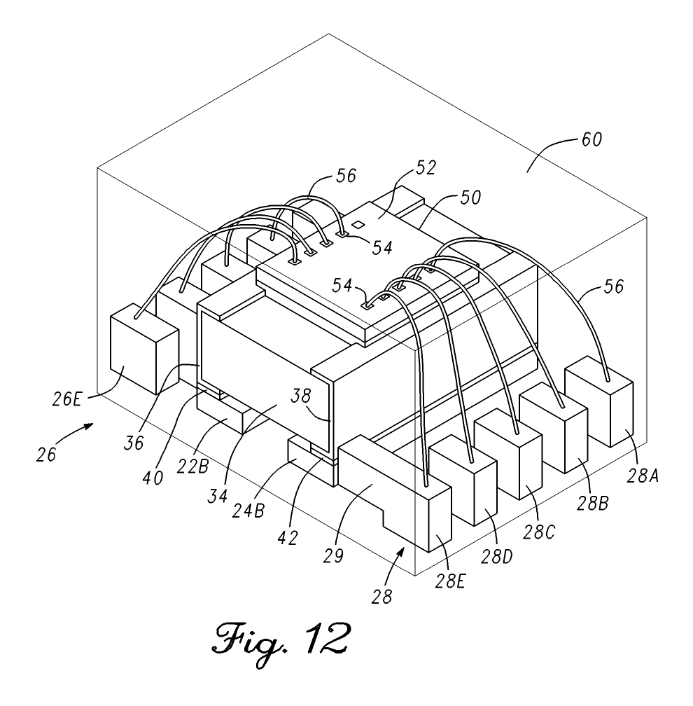

FIG. 12 is an isometric view of the semiconductor component of FIG. 11. FIG. 12 illustrates inductor 34 mounted on thinned conductive strips 22B and 24B, semiconductor chip 50 attached to discrete inductor 34 by a die attach material 46, wire bonds 56 coupling leadframe leads 26 and 28 to bond pads 54, and leadframe lead 28E coupled to thinned conductive pad 24B by leadframe lead 29. Discrete inductor 34, semiconductor chip 50, portions of leadframe leads 26 and 28 and portions of thinned conductive strips 22B and 24B are protected by mold compound 60.

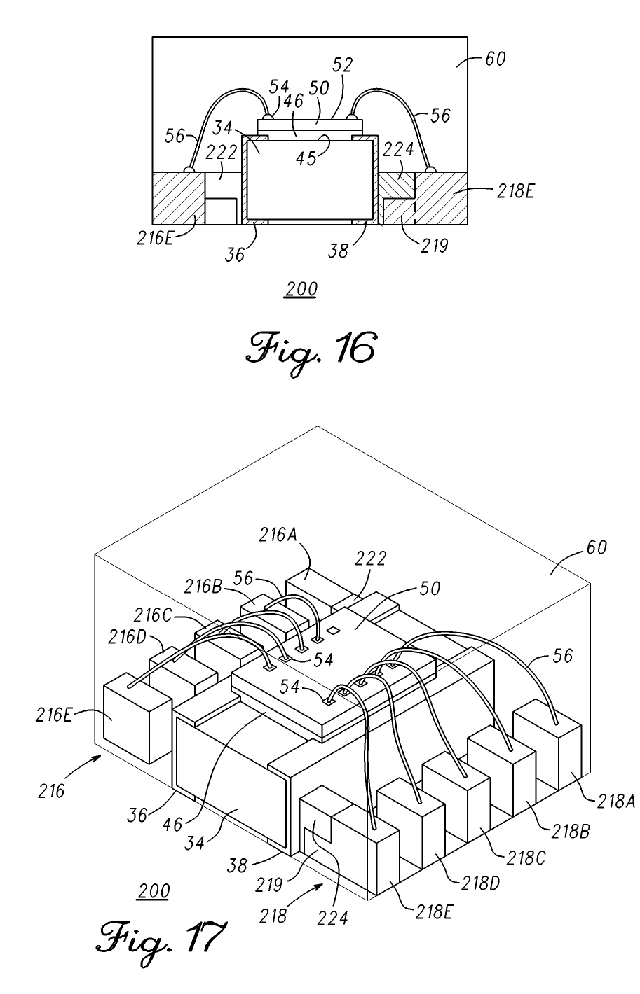

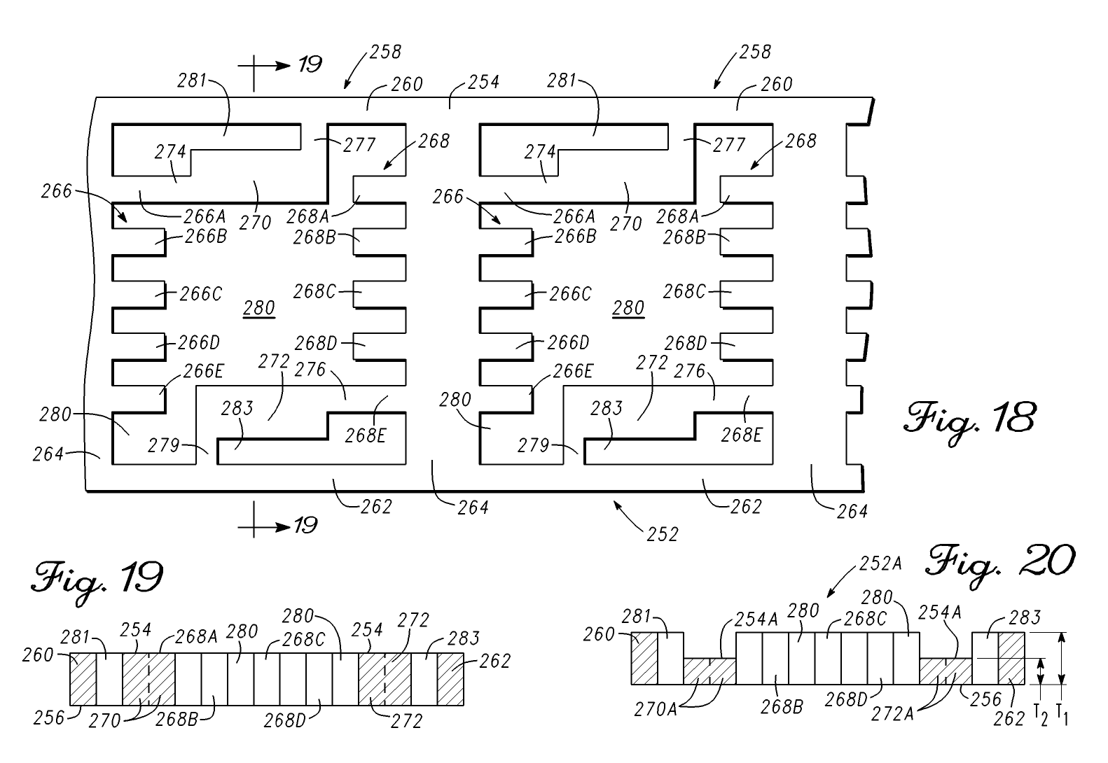

FIG. 13 is a top view of a leadframe 202 used in the manufacture of a semiconductor component 200 (shown in FIGS. 16 and 17) in accordance with another embodiment of the present invention. Leadframe 202 comprises a plurality of semiconductor component sections 204 from which a semiconductor component may be manufactured. Like leadframe 12, leadframe 202 typically comprises a plurality of semiconductor component sections arranged in an M×N peripheral array, where M is the number of rows in the peripheral array and N is the number of columns in the peripheral array. The numbers of rows and columns is not a limitation of the present invention. What is shown in FIG. 13 is a 1×2 array of semiconductor component sections wherein the row has opposing rails 206 and 208 that are coupled to each other by tie-bars 210. Preferably, tie-bars 210 are substantially perpendicular to opposing rails 206 and 208. A semiconductor component section 204 is bounded by opposing rails 206 and 208 and by adjacent tie-bars 210.

A semiconductor component section 204 may comprise leadframe leads 216 that extend from a tie-bar 210 into an opening 220 and leadframe leads 218 that extend from an adjacent tie-bar 210 into opening 220. More particularly, leadframe leads 216A, 216B, 216C, 216D, and 216E extend from one side of tie-bars 210 and leadframe leads 218A, 218B, 218C, 218D, and 218E extend from the opposing side of tie-bars 20. It should be noted that one of leadframe leads 216, e.g., leadframe lead 216A, is longer than leadframe leads 216B-216E. The longer portion of leadframe lead 216A is also referred to as a leadframe lead extension 217. Similarly, one of leadframe leads 218, e.g., leadframe lead 218E, is longer than leadframe leads 218A-218D. The longer portion of leadframe lead 218E is also referred to as a leadframe lead extension 219. Although leadframe lead extensions 217 and 219 are shown as extending from the leadframe leads nearest rails 206 and 208 respectively, i.e., extending from leadframe leads 216A and 218E, the leadframe leads 216 and 218 from which leadframe lead extensions 217 and 219 extend are not limitations of the present invention. For example, leadframe leads 217 and 219 may extend from leadframe leads 216C and 218C or form leadframe leads 216B and 218D, or combinations thereof. Leadframe leads 216 and 218 may be referred to as leadframe fingers and extensions 217 and 219 may be referred to as leadframe lead extensions, leadframe lead extenders, leadframe finger extensions, or leadframe finger extenders. Leadframe leads 216 associated with a semiconductor component section 204 may be referred to as a set of leadframe leads. Likewise, leadframe leads 218 associated with a semiconductor component section also may be referred to as a set of leadframe leads.

Suitable materials for leadframe 202 include thermally and electrically conductive materials such as, for example, copper, a copper alloy, aluminum, an aluminum alloy, silver, a silver alloy, or the like. In accordance with some embodiments, leadframe 202 has a thickness ranging from about 50 μm to about 1,000 μm. By way of example, leadframe 202 has a thickness of about 200 μm. Techniques for manufacturing leadframes are known to those skilled in the art. It should be noted that the technique for manufacturing leadframe 202, the number of leadframe leads, the number of semiconductor component sections, and the thickness of leadframe 202 are not limitations of the present invention.

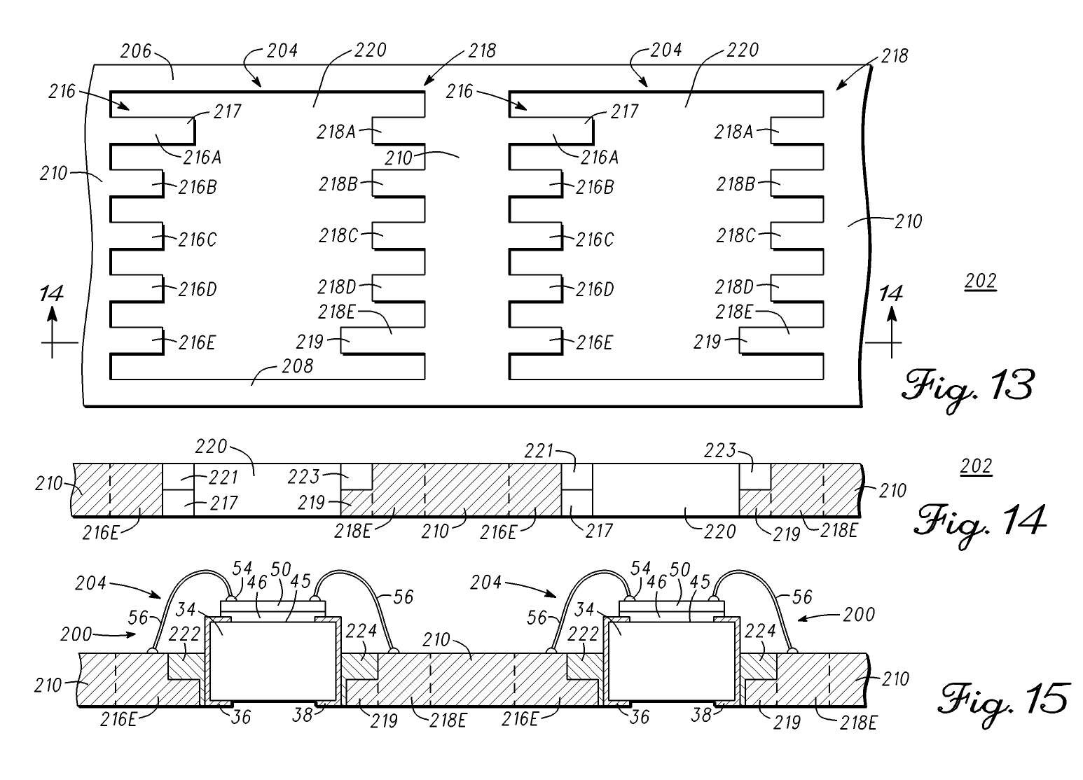

FIG. 14 is a cross-sectional view of leadframe 202 taken along section line 14-14 of FIG. 13. FIG. 14 illustrates leadframe leads 216E spaced apart from extensions 218E by openings 220. In addition, FIG. 14 illustrates leadframe leads 216 extending from one side of tie-bars 210 and leadframe leads 218 extending from an opposing side of adjacent tie-bars 210. Although not shown in the cross-sectional view of FIG. 14, a leadframe lead extension 216A extends from one leadframe lead of the set of leadframe leads 216. For the sake of clarity, vertical broken lines are used to distinguish leadframe leads 216 and 218, tie-bars 210, and leadframe lead extensions 218A. Preferably, channels 221 and 223 are formed in leadframe lead extensions 217 and 219.

FIG. 15 is a cross-sectional view of semiconductor components 200 during manufacture. FIG. 15 illustrates discrete passive components 34 mounted to each semiconductor component section 204. In accordance with some embodiments, discrete passive component 34 is a ferrite core inductor having contact terminals 36 and 38 and mating surface 45. Terminal 36 may be coupled to extension 217 by solder 222 that fills channel 221 and terminal 38 may be coupled to extension 219 by solder 224 that fills channel 223.

A die attach material 46 is disposed on mating surfaces 45 and portions of contact terminals 36 and 38 of ferrite core inductors 34. In accordance with some embodiments, die attach material 46 is thermally conductive and electrically nonconductive. Suitable die attach materials include an electrically non-conductive epoxy, a die attach film, or the like. A semiconductor chip 50 is mounted in die attach material 46 and die attach material 46 is cured.

Preferably, each semiconductor chip 50 has a surface 52 on which a plurality of bond pads 54 are formed. Bond pads 54 are electrically coupled to corresponding leadframe leads 216 and 218 using, for example, wire bonds 56, wedge bonds, ball bonds, or the like. Wire bonds 56 are also referred to as bonding wires. The means for electrically coupling bond pads 54 to the corresponding leadframe leads 216 and 218 is not a limitation of the present invention. Discrete passive components 34, semiconductor chips 50, bond pads 54, and wire bonds 56 have been discussed with reference to FIGS. 4 and 5.

FIG. 16 illustrates a singulated semiconductor component 200 after encapsulation in a mold compound 60 and singulation into an individual semiconductor component.

FIG. 17 is an isometric view of the semiconductor component of FIG. 16. FIG. 17 illustrates inductor 34 positioned laterally adjacent to leadframe leads 216 and 218 of leadframe 202 and attached to leadframe 202 by solder 222 and 224, semiconductor chip 50 attached to discrete inductor 34 by a die attach material 46, and wire bonds 56 coupling leadframe leads 216 and 218 to bond pads 54. Discrete inductor 34, including portions of contact terminals 36 and 38, and portions of leadframe leads 216 and 218 are exposed, whereas semiconductor chip 50 and wire bonds 56 are protected by mold compound 60.

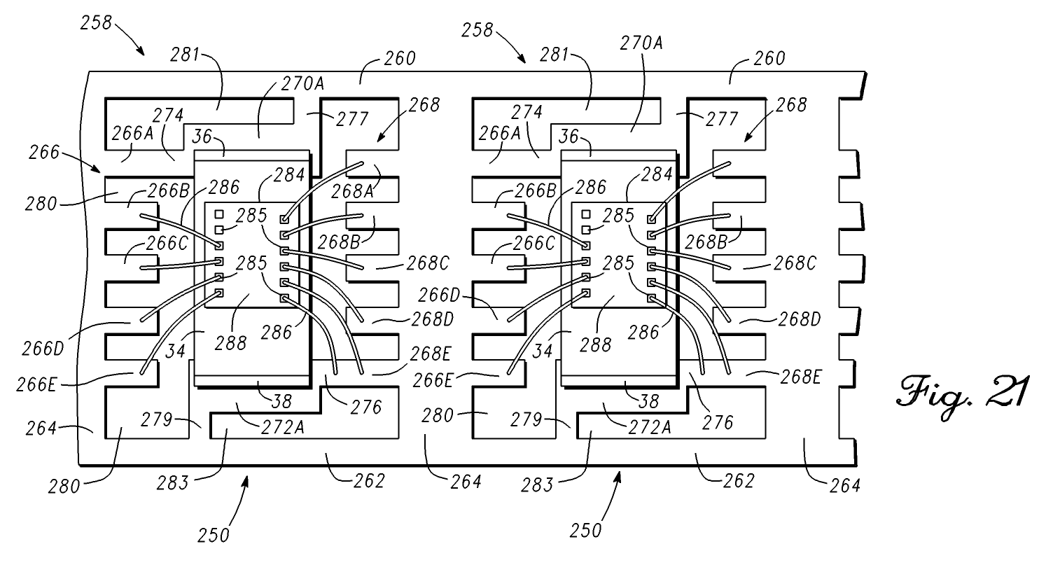

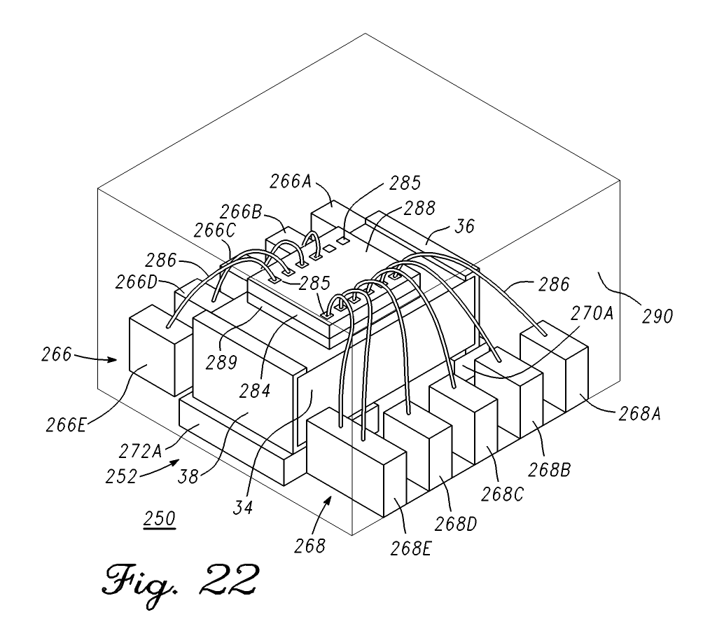

FIG. 18 is a top view of a leadframe 252 having opposing surfaces 254 and 256 used in the manufacture of a semiconductor component 250 (shown in FIGS. 21 and 22) in accordance with an embodiment of the present invention. (Surface 256 is shown in FIGS. 19 and 20). Surface 254 is also referred to as a top surface and surface 256 is also referred to as a bottom surface. Leadframe 252 comprises a plurality of semiconductor component sections 258 from which a semiconductor component may be manufactured. Similar to leadframe 12, the plurality of semiconductor component sections 258 of leadframe 252 is arranged in an M×N peripheral array, where M is the number of rows in the peripheral array and N is the number of columns in the peripheral array. The numbers of rows and columns is not a limitation of the present invention. What is shown in FIG. 18 is a 1×2 array of semiconductor component sections wherein the row has opposing rails 260 and 262 that are coupled to each other by tie-bars 264. Preferably, tie-bars 264 are substantially perpendicular to opposing rails 260 and 262. In accordance with some embodiments, each semiconductor component section 258 is bounded by opposing rails 260 and 262 and by adjacent tie-bars 264.

A semiconductor component section 258 may comprise leadframe leads 266 that extend from a tie-bar 264 into an opening 280 and leadframe leads 268 that extend from an adjacent tie-bar 264 into opening 280. More particularly, leadframe leads 266A, 266B, 266C, 266D, and 266E extend from one side of tie-bars 264 and leadframe leads 268A, 268B, 268C, 268D, and 268E extend from the opposing side of an adjacent tie-bar 264. It should be noted that one of leadframe leads 266, e.g., leadframe lead 266A, is longer than leadframe leads 266B-266E and is connected to one side of a conductive pad or paddle 270. Another side of conductive paddle 270 is connected to rail 260 by a conductive support 277. The longer portion of leadframe lead 266A is also referred to as a leadframe lead extension 274. Similarly, one of leadframe leads 268, e.g., leadframe lead 268E, is longer than leadframe leads 268A-268D and is connected to one side of a conductive pad or paddle 272. Another side of conductive paddle 272 is connected to rail 262 by a conductive support 279. The longer portion of leadframe lead 268E is also referred to as a leadframe lead extension 276. Although leadframe lead extensions 274 and 276 are shown as extending from the leadframe leads nearest rails 260 and 262 respectively, e.g., extending from leadframe leads 266A and 268E, the leadframe leads 266 and 268 from which leadframe lead extensions 274 and 276 extend are not limitations of the present invention. For example, leadframe leads 274 and 276 may extend from leadframe leads 266C and 268C or form leadframe leads 266B and 268D, or combinations thereof. Leadframe leads 266 and 268 may be referred to as leadframe fingers and extensions 274 and 276 may be referred to as leadframe lead extensions, leadframe lead extenders, leadframe finger extensions, or leadframe finger extenders. Leadframe leads 266 associated with a semiconductor component section 258 may be referred to as a set of leadframe leads. Likewise, leadframe leads 268 associated with a semiconductor component section 258 may be referred to as a set of leadframe leads. Openings 281 are bounded by rail 260, conductive pads 270, leadframe lead extensions 274, and conductive supports 277 and openings 283 are bounded by rail 262, conductive pads 272, leadframe lead extensions 276, and conductive supports 279.

Suitable materials, thicknesses, and methods for manufacturing leadframe 252 are the same as those described with reference to leadframe 12. It should be noted that the technique for manufacturing leadframe 252, the number of leadframe leads, the number of semiconductor component sections, and the thickness of leadframe 252 are not limitations of the present invention.

FIG. 19 is a cross-sectional view of leadframe 252 taken along section line 19-19 of FIG. 18. Conductive pads 270 and 272 are spaced apart from rails 260 and 262, respectively, by openings 280. Although leadframe lead 268A is hidden from view by conductive pad 270, its location is identified by broken lines and reference character 268A. Similarly, the location of leadframe lead 268E is hidden from view by conductive pad 272 and is identified by a broken line and reference character 268E.

FIG. 20 is a cross-sectional view of leadframe 252 shown in FIG. 19 after conductive pads 270 and 272 have been thinned. In accordance with one embodiment, conductive pads 270 and 272 are thinned from surface 254 into leadframe 252 to have a thickness of about one-half of their thicknesses before thinning. For example, when leadframe 252 has a thickness, T₁, of about 200 μm, conductive pads 270 and 272 are thinned from about 200 μm to a thickness, T₂, of about 100 μm. The thinned conductive pads are identified by reference characters 270A and 272A, their top surfaces are identified by reference character 254A and the leadframe is identified by reference character 252A. It should be noted that the thinning from top surface 254 preferably does not remove leadframe material from bottom surface 256. Techniques for thinning leadframe 252 have been described with reference to FIG. 3. The method for thinning leadframe 252 and the final thickness of conductive pads 270 and 272 are not limitations of the present invention. For example, thinned conductive pads 270 and 272 may have a thickness of less than about 200 μm, less than about 100 μm, less than about 50 μm, etc.

Although leadframe 252 is shown and described as being thinned from surface 254, it should be noted this is not a limitation of the present invention. For example, leadframe 252 may be thinned from surfaces 254 and 256 in a similar fashion as leadframe 12 was thinned to form leadframe 12B (described with reference to FIG. 9).

FIG. 21 is a top view of the plurality of semiconductor components 250 in accordance with an embodiment of the present invention. FIG. 21 illustrates contact terminals 36 and 38 of ferrite core inductors 34 coupled to conductive pads 270A and 272A, respectively, of semiconductor component sections 258. A semiconductor chip 284 having bond pads 285 is attached to each ferrite core inductor 34 using a die attach material 289 disposed on surface 288 (shown in FIG. 22). Bond pads 285 are electrically coupled to the corresponding leadframe leads 266 and 268. Leadframe lead 268E is coupled to two bond pads by two wire bonds 286 whereas leadframe leads 268A-268D are coupled to single bond pads 285 by single wire bonds 286. It should be noted that the present invention is not limited in this regard. For example, one or more bond pads may be coupled to one or more of leadframe leads 266A-266E, one or more bond pads may be coupled to one or more of leadframe leads 268A-268E, or one or more bond pads may be coupled one or more of leadframe leads 266A-266E and one or more bond pads may be coupled one or more of leadframe leads 268A-268E.

Leadframe 252 on which ferrite core inductors 34 and semiconductor chips 280 are mounted is placed in a mold assembly (not shown) An encapsulating material such as, for example, a mold compound 290 (shown in FIG. 22), is injected into the mold assembly and cured. Semiconductor component sections 258 are then singulated from the leadframe assembly.

FIG. 22 is an isometric view of a semiconductor component 250 after encapsulation in a mold compound 290 and singulation into individual semiconductor components. FIG. 22 illustrates inductor 34 positioned vertically adjacent to conductive pads 270A and 272A of leadframe 252, semiconductor chip 284 attached to discrete inductor 34 by a die attach material 289, and wire bonds 286 coupling leadframe leads 266 and 268 to bond pads 285. Preferably inductor 34 is electrically coupled to conductive pads 270A and 272A of leadframe 252 by solder; however, the technique for electrically coupling inductor 34 to conductive pads 270A and 272A of leadframe 252 is not a limitation of the present invention. For the sake of clarity, the solder is not shown. Other techniques may be used to couple inductor 34 to conductive pads 270A and 272A. Portions of leadframe leads 266 and 268, and portions of thinned conductive pads 270A and 272A are exposed, whereas inductor 34, contact terminals 36 and 38, semiconductor chip 284 and wire bonds 286 are protected by mold compound 290.

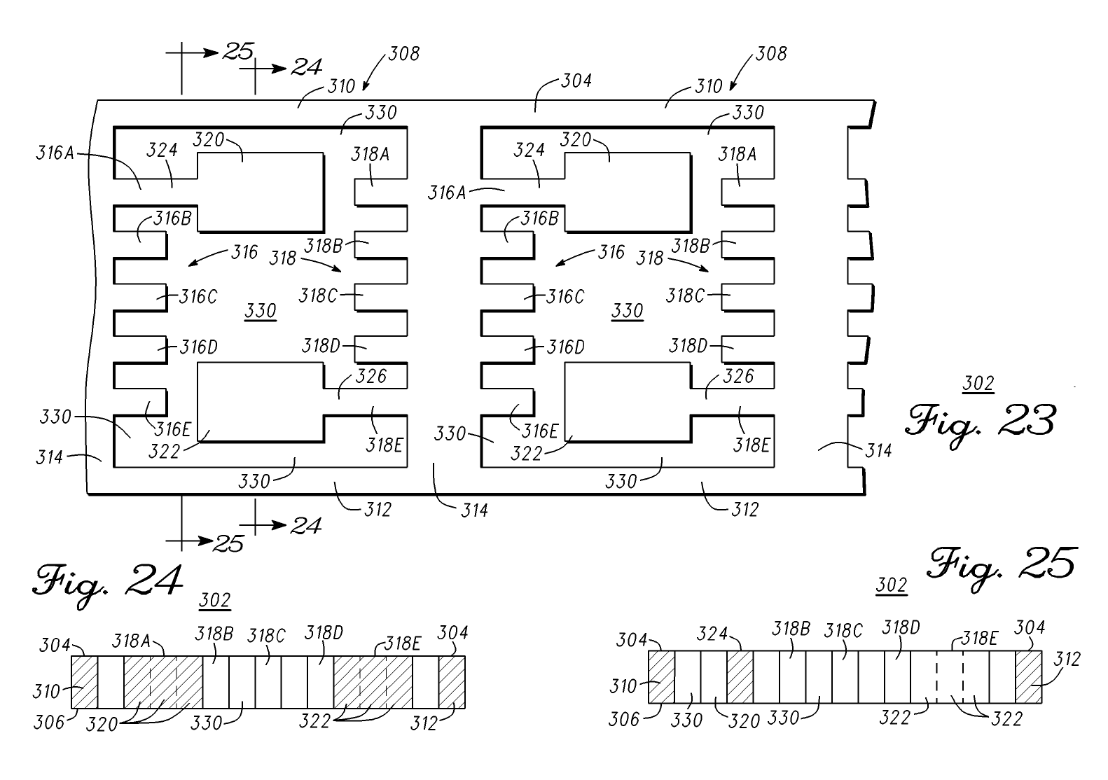

FIG. 23 is a top view of a leadframe 302 having opposing surfaces 304 and 306 used in the manufacture of a semiconductor component 300 in accordance with another embodiment of the present invention. (Surfaces 304 and 306 is shown in FIGS. 24-26). Surface 304 is also referred to as a top surface and surface 306 is also referred to as a bottom surface. Leadframe 302 comprises a plurality of semiconductor component sections 308 from which a semiconductor component may be manufactured. Similar to leadframe 252, the plurality of semiconductor component sections 308 of leadframe 302 is arranged in an M×N peripheral array, where M is the number of rows in the peripheral array and N is the number of columns in the peripheral array. The numbers of rows and columns is not a limitation of the present invention. What is shown in FIG. 23 is a 1×2 array of semiconductor component sections 308 wherein the row has opposing rails 310 and 312 that are coupled to each other by tie-bars 314. Preferably, tie-bars 314 are substantially perpendicular to opposing rails 310 and 312. In accordance with some embodiments, each semiconductor component section 308 is bounded by opposing rails 310 and 312 and by adjacent tie-bars 314.

A semiconductor component section 308 may comprise leadframe leads 316 that extend from a tie-bar 314 into an opening 330 and leadframe leads 318 that extend from an adjacent tie-bar 314 into opening 330. More particularly, leadframe leads 316A, 316B, 316C, 316D, and 316E extend from one side of tie-bars 314 and leadframe leads 318A, 318B, 318C, 318D, and 318E extend from the opposing side of tie-bars 314. It should be noted that one of leadframe leads 316, e.g., leadframe lead 316A, is longer than leadframe leads 316B-316E and is connected to a conductive pad or paddle 320. The longer portion of leadframe lead 316A is also referred to as a leadframe lead extension 324. Similarly, one of leadframe leads 318, e.g., leadframe lead 318E, is longer than leadframe leads 318A-318D and is connected to a conductive pad or paddle 322. The longer portion of leadframe lead 318E is also referred to as a leadframe lead extension 326. Although leadframe lead extensions 324 and 326 are shown as extending from the leadframe leads nearest rails 310 and 312 respectively, e.g., extending from leadframe leads 316A and 318E, the leadframe leads 316 and 318 from which leadframe lead extensions 324 and 326 extend is not a limitation of the present invention. For example, leadframe leads 324 and 326 may extend from leadframe leads 316C and 318C or form leadframe leads 316B and 318D, or combinations thereof. Leadframe leads 316 and 318 may be referred to as leadframe fingers and extensions 324 and 326 may be referred to as leadframe lead extensions, leadframe lead extenders, leadframe finger extensions, or leadframe finger extenders. Leadframe leads 316 associated with a semiconductor component section 308 may be referred to as a set of leadframe leads. Likewise, leadframe leads 318 associated with a semiconductor component section 308 may be referred to as a set of leadframe leads. Although not shown, it should be noted that conductive pads 320 and 322 may be connected to rails 310 and 312, respectively, using conductive supports similar to conductive supports 277 and 279 described with reference to FIG. 18.

Suitable materials for leadframe 302 include thermally and electrically conductive materials such as, for example, copper, a copper alloy, aluminum, an aluminum alloy, silver, a silver alloy, or the like. In accordance with some embodiments, leadframe 302 has a thickness ranging from about 50 μm to about 1,000 μm. By way of example, leadframe 302 has a thickness of about 200 μm. Techniques for manufacturing leadframes are known to those skilled in the art. It should be noted that the technique for manufacturing leadframe 302, the number of leadframe leads, the number of semiconductor component sections 308, and the thickness of leadframe 302 are not limitations of the present invention.

FIG. 24 is a cross-sectional view of leadframe 302 taken along section line 24-24 of FIG. 23. What is shown in FIG. 24 are conductive pads 320 and 322 spaced apart from rails 310 and 312, respectively, by opening 330. Although leadframe lead 318A is hidden from view by conductive pad 320, its location is identified by broken lines and reference character 318A. Similarly, the location of leadframe lead 318E is hidden from view by conductive pad 322 and is identified by a broken line and reference character 318E.

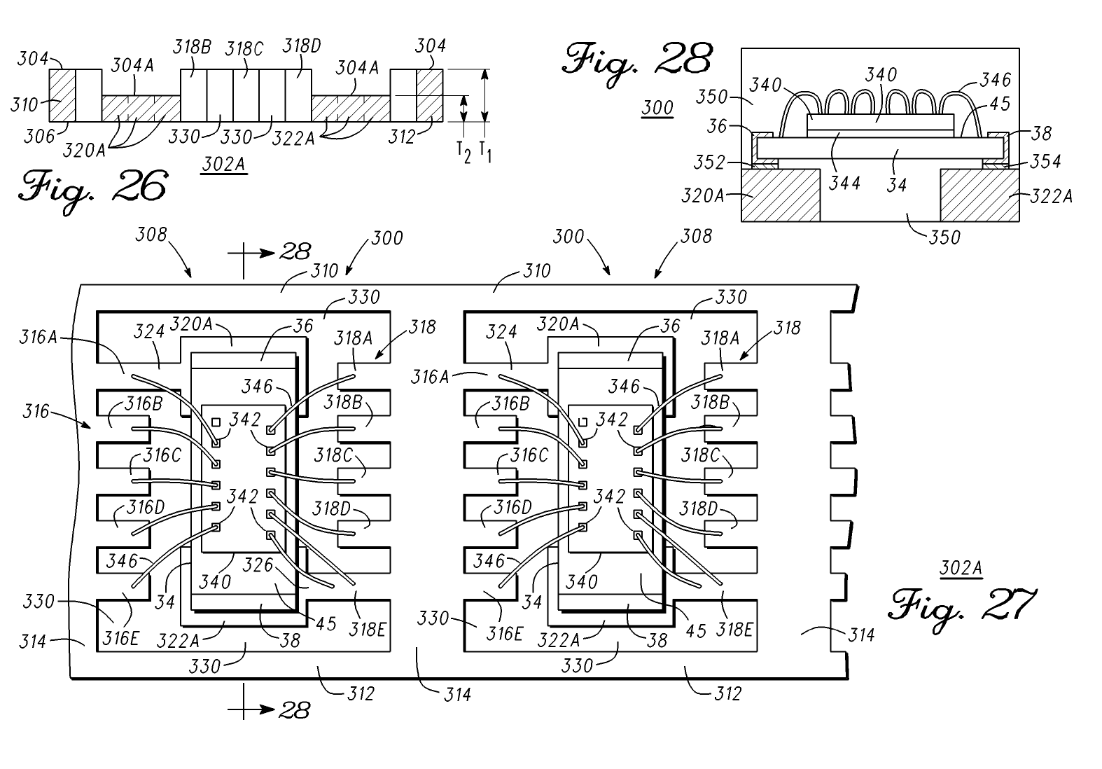

FIG. 25 is a cross-sectional view of leadframe 302 taken along section line 25-25 of FIG. 23. What is shown in FIG. 25 is leadframe lead extension 324 spaced apart from rails 310 and 312, respectively, by opening 330. Although leadframe lead 318E is hidden from view by conductive pad 322, its location is identified by broken lines and reference character 318E.

FIG. 26 is a cross-sectional view of leadframe 302 shown in FIG. 24 after conductive pads 320 and 322 and leadframe lead extensions 324 and 326 have been thinned. In accordance with one embodiment, conductive pads 320 and 322 and leadframe lead extensions 324 and 326 are thinned from surface 304 into leadframe 302 to have a thickness of about one-half of their thicknesses before thinning. For example, when leadframe 302 has a thickness, T₁, of about 200 μm, conductive pads 320 and 322 are thinned from about 200 μm to a thickness, T₂, of about 100 μm. The thinned conductive pads are identified by reference characters 320A and 322A, their top surfaces are identified by reference character 304A, and the leadframe is identified by reference character 302A. It should be noted that the thinning from top surface 304 preferably does not remove leadframe material from bottom surface 306. Techniques for thinning leadframe 302 have been described with reference to FIG. 3. The method for thinning leadframe 302 and the final thickness of conductive pads 320A and 322A are not limitations of the present invention. For example, thinned conductive pads 320A and 322A may have a thickness of less than about 200 μm, less than about 100 μm, less than about 50 μm, etc.

Although leadframe 302 is shown and described as being thinned from surface 304, it should be noted this is not a limitation of the present invention. For example, leadframe 302 may be thinned from surfaces 304 and 306 in a similar fashion as leadframe 12 was thinned to form leadframe 12B (described with reference to FIG. 9).

FIG. 27 is a top view of the plurality of semiconductor components 300 during manufacture. FIG. 27 illustrates contact terminals 36 and 38 of ferrite core inductors 34 coupled to thinned conductive pads 320A and 322A, respectively, in semiconductor component sections 308. A semiconductor chip 340 having bond pads 342 is attached to each ferrite core inductor 34 using a die attach material 344 (shown in FIG. 28). Bond pads 342 are electrically coupled to the corresponding leadframe leads 316 and 318. Leadframe leads 316A-316E are coupled to single bond pads by single wire bonds. Leadframe lead 318E is coupled to two bond pads by two wire bonds 346 whereas leadframe leads 318A-318D are coupled to single bond pads by single wire bonds 346. It should be noted that the present invention is not limited in this regard. For example, one or more bond pads may be coupled to one or more of leadframe leads 316A-316E, one or more bond pads may be coupled to one or more of leadframe leads 318A-318E, or one or more bond pads may be coupled one or more of leadframe leads 316A-316E and one or more bond pads may be coupled to one or more of leadframe leads 318A-318E.

Leadframe 302A on which ferrite core inductors 34 and semiconductor chips 340 are mounted is placed in a mold assembly (not shown). An encapsulating material such as, for example, a mold compound 350 (shown in FIG. 28) is injected into the mold assembly and cured. Semiconductor component sections 308 are then singulated from the leadframe assembly.

FIG. 28 is a cross-sectional view of a semiconductor component 300 after encapsulation in a mold compound 350 and singulation into an individual semiconductor component. FIG. 28 illustrates inductor 34 positioned vertically adjacent to thinned conductive pads 320A and 322A of leadframe 302A and attached to leadframe 302A by solder 352 and 354, and semiconductor chip 340 attached to discrete ferrite core inductor 34 by a die attach material 344. Portions of thinned conductive pads 320A and 322A of leadframe 302A are exposed, whereas inductor 34, contact terminals 36 and 38, and semiconductor chip 340 are protected by mold compound 350.

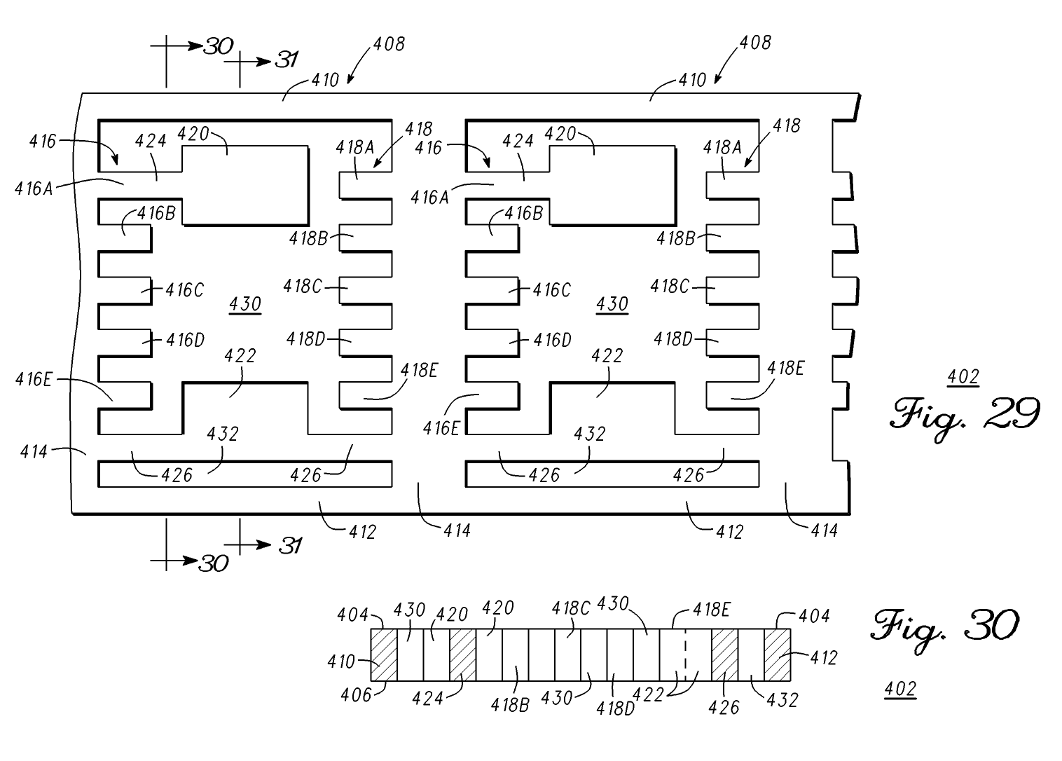

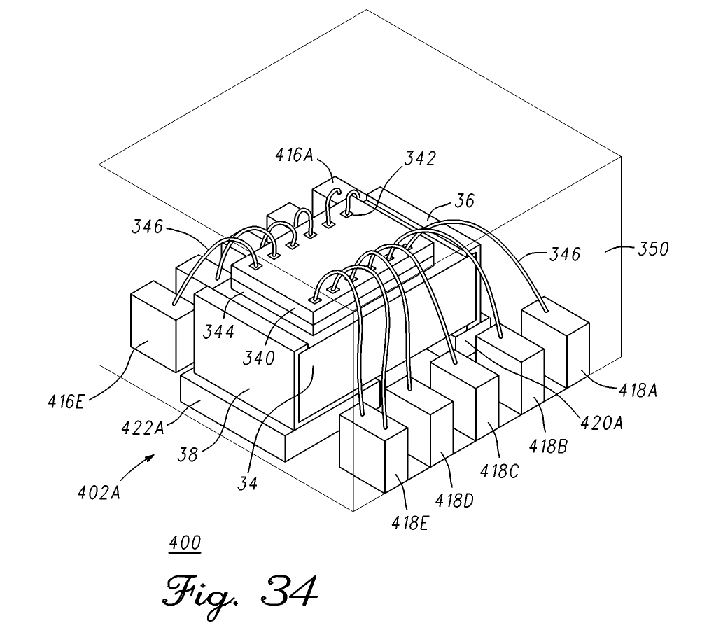

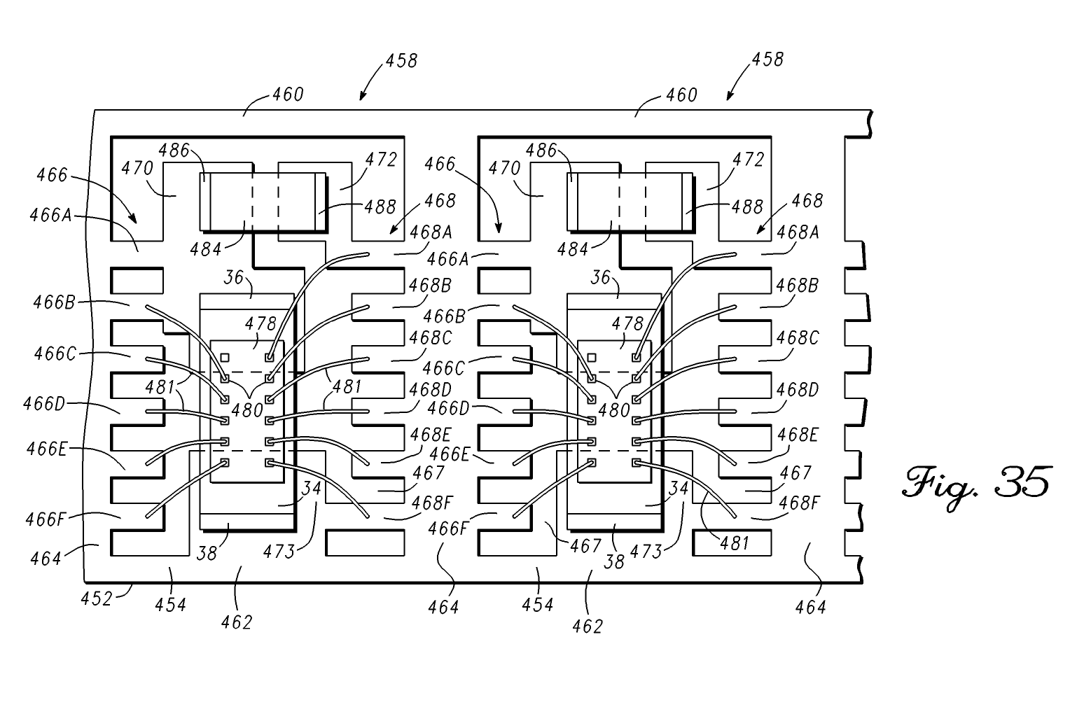

FIG. 29 is a top view of a leadframe 402 having opposing surfaces 404 and 406 used in the manufacture of a semiconductor component 400 in accordance with an embodiment of the present invention. (Surfaces 404 and 406 are shown in FIGS. 30-32 and semiconductor component 400 is shown in FIG. 34). Surface 404 is also referred to as a top surface and surface 406 is also referred to as a bottom surface. Leadframe 402 comprises a plurality of semiconductor component sections 408 from which a semiconductor component may be manufactured. Similar to leadframe 252, the plurality of semiconductor component sections 408 of leadframe 402 is arranged in an M×N peripheral array, where M is the number of rows in the peripheral array and N is the number of columns in the peripheral array. The numbers of rows and columns is not a limitation of the present invention. What is shown in FIG. 29 is a 1×2 array of semiconductor component sections wherein the row has opposing rails 410 and 412 that are coupled to each other by tie-bars 414. Preferably, tie-bars 414 are substantially perpendicular to opposing rails 410 and 412. In accordance with some embodiments, each semiconductor component section 408 is bounded by opposing rails 410 and 412 and by adjacent tie-bars 414.

Semiconductor component sections 408 may comprise leadframe leads 416 that extend from a tie-bar 414 into an opening 430 and leadframe leads 418 that extend from an adjacent tie-bar 414 into opening 430. More particularly, leadframe leads 416A, 416B, 416C, 416D, and 416E extend from one side of tie-bars 414 and leadframe leads 418A, 418B, 418C, 418D, and 418E extend from the opposing sides of adjacent tie-bars 414. It should be noted that one of leadframe leads 416, e.g., leadframe lead 416A, is longer than leadframe leads 416B-416E and is connected to a conductive pad or paddle 420. The longer portion of leadframe lead 416A is also referred to as a leadframe lead extension 424. Although leadframe lead extension 424 is shown as extending from the leadframe lead nearest rail 410, e.g., extending from leadframe leads 416A, the leadframe lead 416 from which leadframe lead extensions 424 extend and the number of leadframe lead extensions are not limitations of the present invention. For example, leadframe leads 424 may extend from leadframe leads 416C, or form leadframe leads 416B, or combinations thereof. Leadframe leads 416 and 418 may be referred to as leadframe fingers and extensions 424 may be referred to as leadframe lead extensions, leadframe lead extenders, leadframe finger extensions, or leadframe finger extenders. Leadframe leads 416 associated with a semiconductor component section 408 may be referred to as a set of leadframe leads. Likewise, leadframe leads 418 associated with a semiconductor component section 408 may be referred to as a set of leadframe leads. Although not shown, it should be noted that conductive pad 420 may be connected to rail 410 using conductive supports similar to conductive supports 277 and 279 described with reference to FIG. 18.

A conductive pad or paddle 422 is coupled to tie-bars 414 by sacrificial leads 426. Leads 426 are referred to as sacrificial leads because they are cut during singulation, which leaves conductive pad 422 electrically isolated from tie-bars 414. Conductive pad 422 and sacrificial leads 426 are spaced apart from rail 412 by an opening 432.

Suitable materials for a leadframe such as leadframe 402 have been described with reference to leadframe 12.

FIG. 30 is a cross-sectional view of leadframe 402 taken along section line 30-30 of FIG. 29. What is shown in FIG. 30 is leadframe lead extension 424 and sacrificial lead 426 spaced apart from rails 410 and 412 by openings 430 and 432, respectively. Although leadframe lead 418E is hidden from view by conductive pad 422, its location is identified by broken lines and reference character 418E.

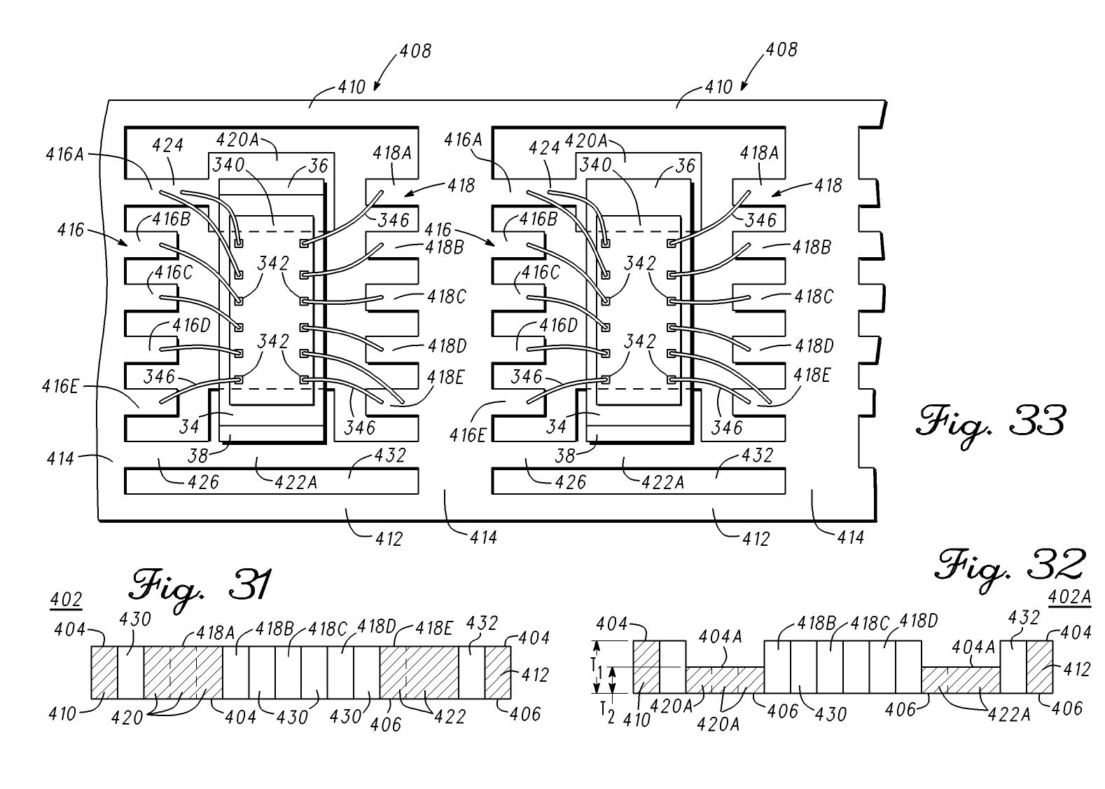

FIG. 31 is a cross-sectional view of leadframe 402 taken along section line 31-31 of FIG. 29. What is shown in FIG. 31 are conductive pads 420 and 422 spaced apart from rails 410 and 412 by openings 430 and 432, respectively. Although leadframe lead 418A is hidden from view by conductive pad 420, its location is identified by broken lines and reference character 41 8A. Similarly, the location of leadframe lead 418E is hidden from view by conductive pad 422 and is identified by a broken line and reference character 418E.

FIG. 32 is a cross-sectional view of leadframe 402 shown in FIG. 31 after conductive pads 420 and 422 and leadframe lead extension 424 have been thinned. In accordance with an embodiment of the present invention, conductive pads 420 and 422 and leadframe lead extension 424 are thinned from surface 404 into leadframe 402 to have a thickness of about one-half of their thicknesses before thinning. For example, when leadframe 402 has a thickness, T₁, of about 200 μm, conductive pads 420 and 422 are thinned from about 200 μm to a thickness, T₂, of about 100 μm. The thinned conductive pads are identified by reference characters 420A and 422A, their top surfaces are identified by reference character 404A, and the leadframe is identified by reference character 402A. It should be noted that the thinning from top surface 404 preferably does not remove leadframe material from bottom surface 406. Techniques for thinning leadframe 402 have been described with reference to FIG. 3. The method for thinning leadframe 402 and the final thickness of conductive pads 420 and 422 are not limitations of the present invention. For example, thinned conductive pads 420A and 422A may have a thickness of less than about 200 μm, less than about 100 μm, less than about 50 μm, etc.

Leadframe 402 is shown and described as being thinned from surface 404, however it should be noted this is not a limitation of the present invention. For example, leadframe 402 may be thinned from surfaces 404 and 406 in a similar fashion as leadframe 12 was thinned to form leadframe 12B (described with reference to FIG. 9).

FIG. 33 is a top view of the plurality of semiconductor components 400 in accordance with an embodiment of the present invention. What is shown in FIG. 33 are contact terminals 36 and 38 of ferrite core inductors 34 coupled to conductive pads 420A and 422A, respectively, of semiconductor component sections 408. A semiconductor chip 340 having bond pads 342 is attached to each ferrite core inductor 34 using a die attach material 344 (shown in FIG. 34). Bond pads 342 are electrically coupled to the corresponding leadframe leads 416 and 418. Leadframe lead 416A is coupled to two bond pads by two wire bonds 346 whereas leadframe leads 416B-416E are coupled to single bond pads by single wire bonds. Similarly, leadframe lead 418E is coupled to two bond pads by two wire bonds 346 whereas leadframe leads 418A-418D are coupled to single bond pads by single wire bonds. It should be noted that the present invention is not limited in this regard. For example, one or more bond pads may be coupled to one or more of leadframe leads 416A-416E, one or more bond pads may be coupled to one or more of leadframe leads 418A-418E, or one or more bond pads may be coupled one or more of leadframe leads 416A-416E and one or more bond pads may be coupled one or more of leadframe leads 418A-418E.

Leadframe 402 on which ferrite core inductors 34 and semiconductor chips 340 are mounted is placed in a mold assembly (not shown). An encapsulating material such as, for example, a mold compound 350 (shown in FIG. 34) is injected into the mold assembly and cured. Semiconductor component sections 408 are then singulated from the leadframe assembly.

FIG. 34 is an isometric view of a semiconductor component 400 after encapsulation in mold compound 350 and singulation into individual semiconductor components. FIG. 34 illustrates inductor 34 positioned vertically adjacent to thinned conductive pads 420A and 422A of leadframe 402A and electrically coupled to leadframe 402A, and semiconductor chip 340 attached to discrete ferrite core inductor 34 by a die attach material 344. Preferably inductor 34 is electrically coupled to thinned conductive pads 420A and 422A of leadframe 402A by solder (not shown); however, the technique for electrically coupling inductor 34 to thinned conductive pads 420A and 422A of leadframe 402A is not a limitation of the present invention. Other techniques for coupling inductor 34 to conductive pads 420A and 422A may be used. Portions of thinned conductive pads 420A and 422A and leadframe leads 416 and 418 of leadframe 402A are exposed, whereas inductor 34, contact terminals 36 and 38, and semiconductor chip 340 are protected by mold compound 350.

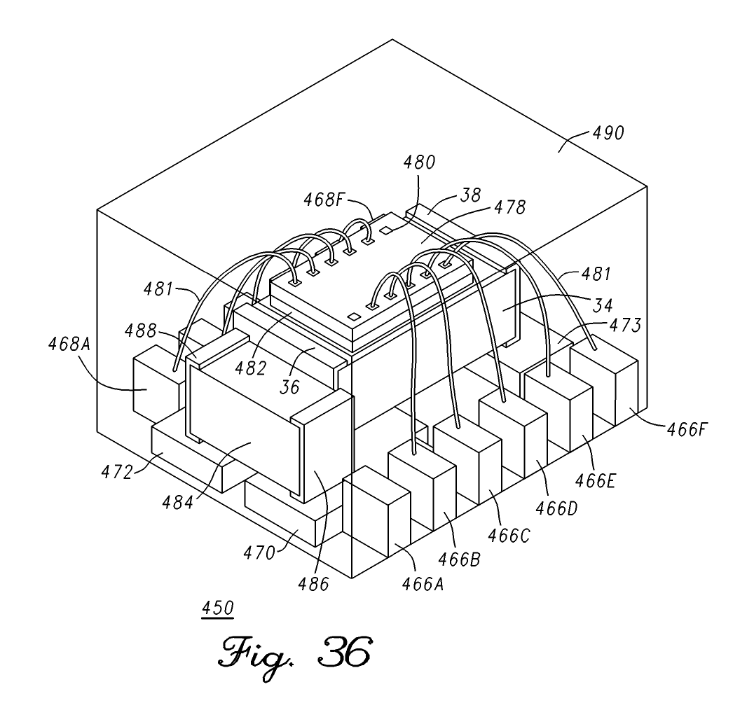

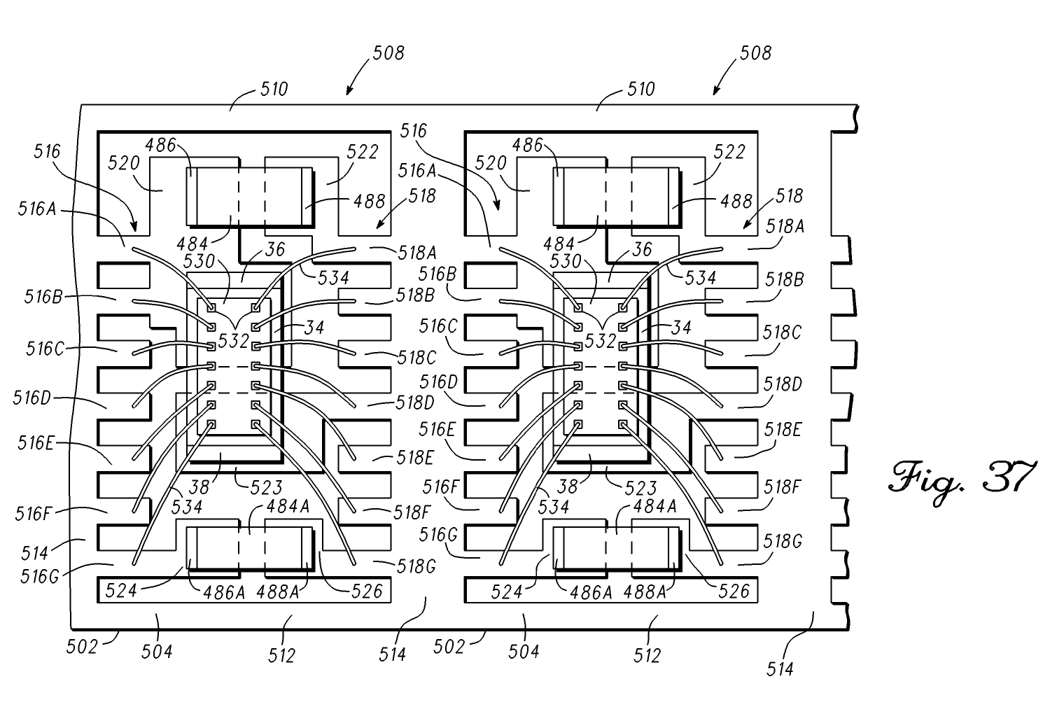

FIG. 35 is a top view of a plurality of semiconductor components 450 (a single semiconductor component is shown in FIG. 36) during manufacture in accordance with another embodiment of the present invention. What is shown in FIG. 35 is a leadframe 452 having a surface 454, which is also referred to as a top surface. Leadframe 452 comprises a plurality of semiconductor component sections 458 from which a semiconductor component may be manufactured. Similar to leadframe 252, the plurality of semiconductor component sections 458 of leadframe 452 is arranged in an M×N peripheral array, where M is the number of rows in the peripheral array and N is the number of columns in the peripheral array. The numbers of rows and columns is not a limitation of the present invention. What is shown in FIG. 35 is a 1×2 array of semiconductor component sections wherein the row has opposing rails 460 and 462 that are coupled to each other by tie-bars 464. Preferably, tie-bars 464 are substantially perpendicular to opposing rails 460 and 462. In accordance with some embodiments of the present invention, each semiconductor component section 458 is bounded by opposing rails 460 and 462 and by adjacent tie-bars 464.

A semiconductor component section 458 may comprise leadframe leads 466 that extend from a tie-bar 464 into opening 467 and leadframe leads 468 that extend from an adjacent tie-bar 464 into opening 467. More particularly, leadframe leads 466A, 466B, 466C, 466D, 466E, and 466F extend from one side of tie-bars 464 and leadframe leads 468A, 468B, 468C, 468D, 468E, and 468F extend from the opposing side of adjacent tie-bars 464. It should be noted that two of leadframe leads 466, e.g., leadframe leads 466A and 466B, are connected to a conductive pad or paddle. Similarly, one of leadframe leads 468, e.g., leadframe lead 468A, is connected to a conductive pad or paddle and one of leadframe leads 468, e.g., leadframe lead 468F is connected to a conductive pad or paddle. Although leadframe leads 466A, 466B, 468A, and 468F that are connected to the conductive pads are shown as being nearest rails 460 and 462, this is not a limitation of the present invention. For example, leadframe lead 466C, 468B, and 468D may be connected to the conductive pads, or other combinations of leadframe leads may be connected to the conductive pads. Leadframe leads 466 and 468 may be referred to as leadframe fingers. Leadframe leads 466 associated with a semiconductor component section 458 may be referred to as a set of leadframe leads. Likewise, leadframe leads 468 associated with a semiconductor component section 458 may be referred to as a set of leadframe leads.

The conductive pads or paddles are thinned to form thinned conductive pads 470, 472, and 473. Thus, leadframe leads 466A and 466B are connected to a thinned conductive pad 470, leadframe lead 468A is connected to a thinned conductive pad 472, and leadframe lead 468F is connected to a thinned conductive pad 473. Methods for thinning the conductive pads have been described with reference to FIGS. 3 and 9.

Contact terminals 36 and 38 of ferrite core inductors 34 are coupled to thinned conductive pads 470 and 473, respectively, of semiconductor component sections 458. A semiconductor chip 478 having bond pads 480 is attached to each ferrite core inductor 34 using a die attach material 482 (shown in FIG. 36). Preferably, bond pads 480 are electrically coupled to the corresponding leadframe leads 466 and 468 by wire bonds 481. It should be noted that the present invention is not limited in this regard. For example, one or more bond pads may be coupled to one or more of leadframe leads 466A-466F, one or more bond pads may be coupled to one or more of leadframe leads 468A-468F, or one or more bond pads may be coupled one or more of leadframe leads 466A-466F and one or more bond pads may be coupled one or more of leadframe leads 468A-468F.

A capacitor 484 having contact terminals 486 and 488 is coupled between thinned conductive pads 470 and 472. For example, contact terminal 486 may be soldered to thinned conductive pad 470 and contact terminal 488 may be soldered to thinned conductive pad 472.

Leadframe 452 on which ferrite core inductors 34, semiconductor chips 478, and capacitors 484 are mounted is placed in a mold assembly (not shown). An encapsulating material such as, for example, a mold compound 490 (shown in FIG. 36) is injected into the mold assembly and cured. Semiconductor component sections 458 are then singulated from the leadframe assembly.

FIG. 36 is an isometric view of a semiconductor component 450 after encapsulation in a mold compound 490 and singulation into an individual semiconductor component. FIG. 36 illustrates inductor 34 positioned vertically adjacent and electrically coupled to thinned conductive pads 470 and 473 of leadframe 452, semiconductor chip 478 attached to discrete ferrite core inductor 34 by a die attach material 482, and chip capacitor 484 electrically coupled to thinned conductive pads 470 and 472 of leadframe 452. Preferably inductor 34 is electrically coupled to thinned conductive pads 470 and 473 of leadframe 452 by solder and chip capacitor 484 is electrically coupled to thinned conductive pads 470 and 472 of leadframe 452 by solder; however, the technique for electrically coupling inductor 34 to thinned conductive pads 470 and 473 and capacitor 484 to thinned conductive pads 470 and 472 of leadframe 452 are not limitations of the present invention. For the sake of clarity, the solder is not shown. Other techniques may be used to couple inductor 34 and capacitor 484 to the conductive pads. Portions of thinned conductive pads 470, 472, and 473 and portions of leadframe leads 416 and 418 of leadframe 452 are exposed, whereas inductor 34, contact terminals 36 and 38, semiconductor chip 478, and capacitor 484 are protected by mold compound 490.

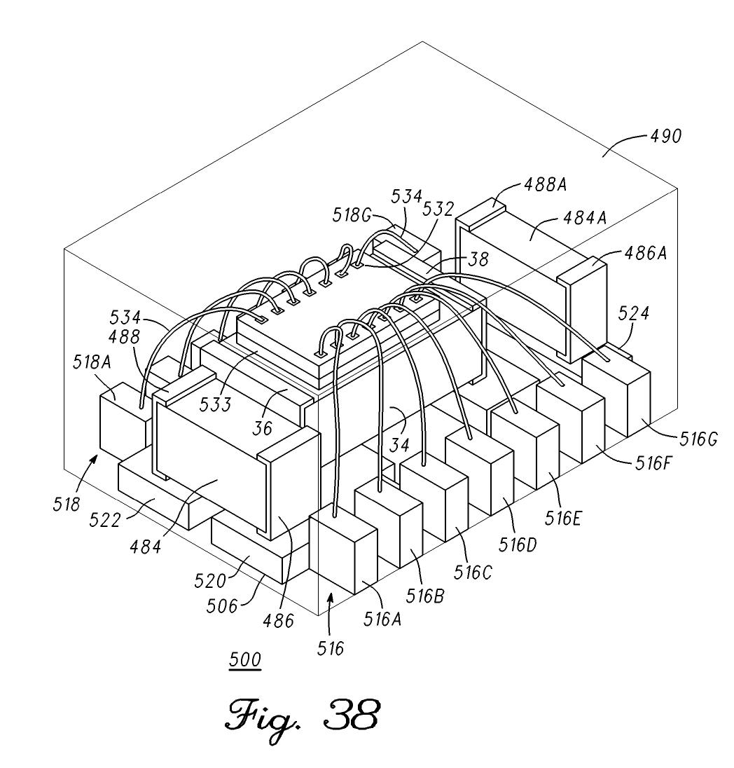

FIG. 37 is a top view of a plurality of semiconductor components 500 (shown in FIG. 38) during manufacture in accordance with another embodiment of the present invention. What is shown in FIG. 37 is a leadframe 502 having opposing surfaces 504 and 506. (Surface 506 is shown in FIG. 38). Surface 504 is also referred to as a top surface and surface 506 is also referred to as a bottom surface. Leadframe 502 comprises a plurality of semiconductor component sections 508 from which a semiconductor component may be manufactured. Similar to leadframe 252, the plurality of semiconductor component sections 508 of leadframe 502 is arranged in an M×N peripheral array, where M is the number of rows in the peripheral array and N is the number of columns in the peripheral array. The numbers of rows and columns is not a limitation of the present invention. What is shown in FIG. 37 is a 1×2 array of semiconductor component sections wherein the row has opposing rails 510 and 512 that are coupled to each other by tie-bars 514. Preferably, tie-bars 514 are substantially perpendicular to opposing rails 510 and 512. In accordance with some embodiments, each semiconductor component section 508 is bounded by opposing rails 510 and 512 and by adjacent tie-bars 514.

A semiconductor component section 508 may comprise leadframe leads 516 that extend from a tie-bar 514 toward leadframe leads 518 that extend from an adjacent tie-bar 514. More particularly, leadframe leads 516A, 516B, 516C, 516D, 516E, 516F, and 516G extend from one side of tie-bars 514 and leadframe leads 518A, 518B, 518C, 518D, 518E, 518F, and 518G extend from the opposing sides of adjacent tie-bars 514. It should be noted that two of leadframe leads 516, e g., leadframe leads 516A and 516B, are connected to a thinned conductive pad or paddle 520 and one of leadframe leads 516, e.g., leadframe lead 516G, is connected to a thinned conductive pad 524. Similarly, one of leadframe leads 518, e.g., leadframe lead 518A, is connected to a thinned conductive pad or paddle 522, one of leadframe leads 518, e.g., 518D, is connected to a thinned conductive pad or paddle 523, and one of leadframe leads 518, e.g., leadframe lead 518G, is connected to a thinned conductive pad or paddle 526. Although leadframe leads 516A, 5168, 516G, 518A, and 518G are connected to conductive pads 520, 522, 524, and 526 are shown as being nearest rails 510 and 512, this is not a limitation of the present invention. For example, leadframe lead 516C, 516D, 518B, and 518C may be connected to thinned conductive pads 520, 522, 523, 524, and 526, respectively, or other combinations of leadframe leads may be connected to thinned conductive pads 520, 522, 523, 524, and 526. Leadframe leads 516 and 518 may be referred to as leadframe fingers. Leadframe leads 516 associated with a semiconductor component section 508 may be referred to as a set of leadframe leads. Likewise, leadframe leads 518 associated with a semiconductor component section 508 may be referred to as a set of leadframe leads.

The conductive pads or paddles are thinned to form thinned conductive pads 520, 522, 523, 524, and 526. Methods for thinning the conductive pads have been described with reference to FIGS. 3 and 9.

Contact terminals 36 and 38 of ferrite core inductors 34 are coupled to thinned conductive pads 520 and 523, respectively, of semiconductor component sections 508. A semiconductor chip 530 having bond pads 532 is attached to each ferrite core inductor 34 using a die attach material 533 (shown in FIG. 38). Preferably, bond pads 532 are electrically coupled to the corresponding leadframe leads 516 and 518 via wire bonds 534. It should be noted that the present invention is not limited in this regard. For example, one or more bond pads may be coupled to one or more of leadframe leads 516A-516G, one or more bond pads may be coupled to one or more of leadframe leads 518A-518G, or one or more bond pads may be coupled one or more of leadframe leads 516A-516G and one or more bond pads may be coupled one or more of leadframe leads 518A-518G.

A capacitor 484 having contact terminals 486 and 488 is coupled between thinned conductive pads 520 and 522. For example, contact terminal 486 may be soldered to thinned conductive pad 520 and contact terminal 488 may be soldered to thinned conductive pad 522. In addition, a contact terminal 486A of another capacitor 484A is soldered to thinned conductive pad 524 and a contact terminal 488A is soldered to thinned conductive pad 526.

Leadframe 502 on which ferrite core inductors 34, semiconductor chips 530, capacitors 484, and capacitors 484A are mounted is placed in a mold assembly (not shown). An encapsulating material such as, for example, mold compound 490 (shown in FIG. 38) is injected into the mold assembly and cured. Semiconductor component sections 508 are then singulated from the leadframe assembly.

FIG. 38 is an isometric view of a semiconductor component 500 after encapsulation in a mold compound 490 and singulation into an individual semiconductor component. FIG. 38 illustrates inductor 34 positioned vertically adjacent and electrically coupled to thinned conductive pads 520, 522, and 523 of leadframe 502, semiconductor chip 530 attached to discrete ferrite core inductor 34 by a die attach material 533, chip capacitor 484 electrically coupled to thinned conductive pads 520 and 522, and chip capacitor 484A electrically coupled to thinned conductive pads 524 and 526. Preferably inductor 34 is electrically coupled to thinned conductive pads 520 and 523 of leadframe 502 by solder, chip capacitor 484 is electrically coupled to thinned conductive pads 520 and 522 of leadframe 502 by solder, and chip capacitor 484A is electrically coupled to thinned conductive pads 524 and 526 of leadframe 502 by solder; however, the technique for electrically coupling inductor 34 to thinned conductive pads 520 and 523, capacitor 484 to thinned conductive pads 520 and 522 of leadframe 502, and capacitor 484A to thinned conductive pads 524 and 526 are not limitations of the present invention. For the sake of clarity, the solder is not shown. Other techniques may be used to couple inductor 34, and capacitors 484 and 484A to the conductive pads. Portions of thinned conductive pads 520, 522, 523, 524, and 526 and portions of leadframe leads 516 and 518 of leadframe 502 are exposed, whereas inductor 34, contact terminals 36 and 38, semiconductor chip 530, and capacitor 484 and 484A are protected by mold compound 490.

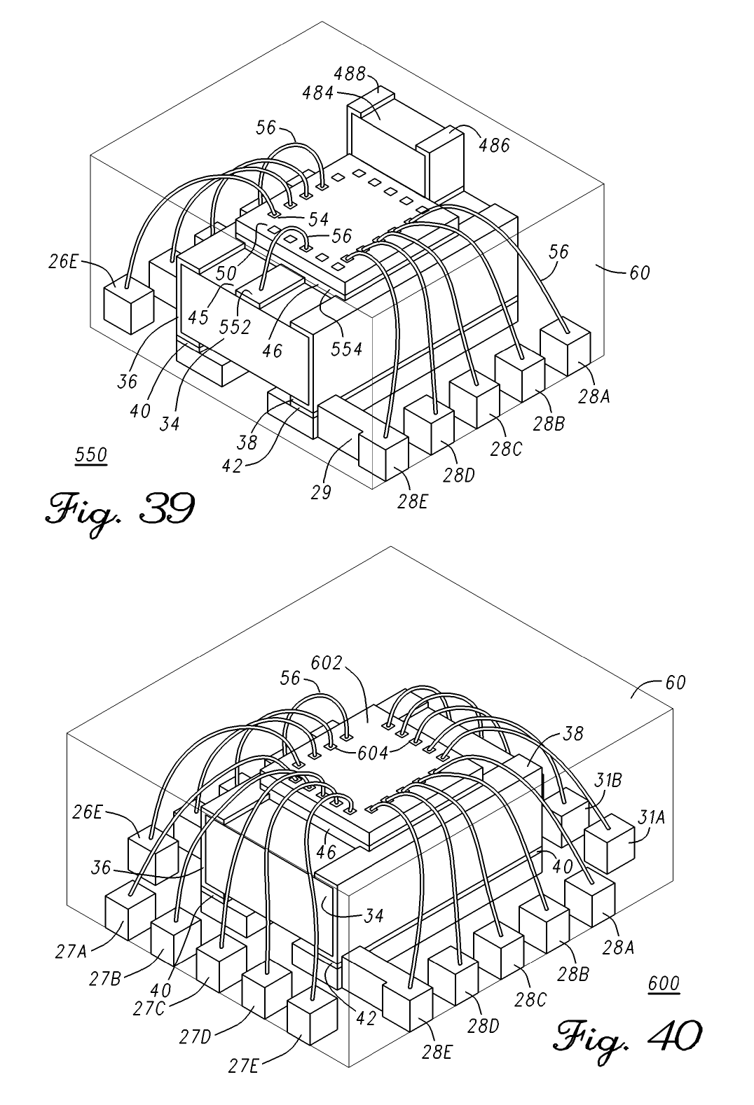

FIG. 39 is an isometric view of a semiconductor component 550 in accordance with another embodiment of the present invention. Semiconductor component 550 is similar to semiconductor component 10 described with reference to FIG. 8, except that a conductive strip 552 is formed on surface 45 of discrete inductor 34. Semiconductor chip 50 is coupled to surface 45 and conductive strip 552 using an electrically insulating die attach material 554. A capacitor 484 having contact terminals 486 and 488 is electrically coupled between contact terminal 36 of discrete ferrite core inductor 34 and conductive strip 552 using, for example, solder (not shown). A bond pad on semiconductor chip 50 is electrically coupled to conductive strip 552 by a wire bond 56. Semiconductor chip 50, inductor 34, capacitor 484, leadframe leads 26A-26E and 28A-28E, and wirebonds 56 are encapsulated within mold compound 60.

FIG. 40 is an isometric view of a semiconductor component 600 packaged in a quad flat pack configuration. Semiconductor component 600 is similar to semiconductor 10 described with reference to FIG. 8 except that leadframe leads are formed around all four side of the inductor-semiconductor chip structure. Accordingly, leadframe leads 27A, 27B, 27C, 27D, and 27E and leadframe leads 31A and 31B are shown in FIG. 40. It should be noted that the remaining leadframe leads located adjacent leadframe lead 31B are hidden from view. In addition, semiconductor chip 602 has bond pads 604 on four sides. Semiconductor chip 602, inductor 34, leadframe leads 26A-26E, 27A-27E, 28A-28E, and 31A-31B, and wirebonds 56 are encapsulated within mold compound 60.

Although specific embodiments have been disclosed herein, it is not intended that the invention be limited to the disclosed embodiments. Those skilled in the art will recognize that modifications and variations can be made without departing from the spirit of the invention. It is intended that the invention encompass all such modifications and variations as fall within the scope of the appended claims.

What is claimed is:

1. A semiconductor component, comprising:
a leadframe having a surface;
a first discrete passive circuit element coupled to a portion of the leadframe; and
an active device coupled to the discrete passive circuit element.

2. The semiconductor component of claim 1, wherein the first discrete passive circuit element comprises one of an inductor, a capacitor, or a resistor.

3. The semiconductor component of claim 1, further including at least one bond wire coupled between the active device and another portion of the leadframe.

4. The semiconductor component of claim 1, wherein the active device is an integrated circuit.

5. The semiconductor component of claim 1, further including a second discrete passive circuit element coupled to the first discrete passive circuit element.

6. The semiconductor component of claim 1, wherein the first discrete passive circuit element is vertically positioned between the surface of the leadframe and the active device.

7. The semiconductor component of claim 1, wherein the leadframe comprises a device receiving area and at least one leadframe lead.

8. The semiconductor component of claim 7, further including at least one bond wire coupled between the at least one leadframe lead and the active device.

9. The semiconductor component of claim 1, further including a die attach material between the first discrete passive circuit element and the leadframe.

10. The semiconductor component of claim 1, further including a mold compound disposed on the active device, a portion of the first discrete passive circuit element, and another portion of the leadframe.

11. The semiconductor component of claim 1, further including a lead free solder between the leadframe and the first passive circuit element.

12. A semiconductor component, comprising:
a leadframe having a first leadframe lead;
a discrete inductor adjacent the first leadframe lead; and
a semiconductor chip over the discrete inductor.

13. The semiconductor component of claim 12, wherein the discrete inductor is laterally adjacent the first leadframe lead.

14. The semiconductor component of claim 13, further including a second leadframe lead and a wire bond coupling the second leadframe lead to the semiconductor chip.

15. The semiconductor component of claim 14, further including an encapsulating material, wherein the discrete inductor and the semiconductor chip are within the encapsulating material.

16. The semiconductor component of claim 14, further including an encapsulating material wherein the semiconductor chip and a portion of the discrete inductor are within the encapsulating material and wherein a portion of the inductor is exposed.

17. The semiconductor component of claim 13, wherein the leadframe has a second leadframe lead and the semiconductor chip has first and second bond pads and further including a first wire bond coupling the first bond pad to the first leadframe lead and a second wire bond coupling the second bond pad to the second leadframe lead.

18. The semiconductor component of claim 17, further including an encapsulating material, wherein the discrete inductor and the semiconductor chip are within the encapsulating material.

19. The semiconductor component of claim 13, wherein the leadframe has a plurality of leadframe leads and the semiconductor chip has a plurality of bond pads and further including a first wire bond coupling a first bond pad of the plurality of bond pads to the first leadframe lead of the plurality of leadframe leads, a second wire bond coupling a second bond pad of the plurality of bond pads to a second leadframe lead of the plurality of leadframe leads, and a third wire bond coupling a third bond pad of the plurality of bond pads to a third leadframe lead of the plurality of leadframe leads.

20. The semiconductor component of claim 13, wherein the discrete inductor is vertically adjacent the first leadframe lead.

21. The semiconductor component of claim 20, further including an encapsulating material, wherein the discrete inductor and the semiconductor chip are within the encapsulating material.

22. The semiconductor component of claim 20, further including an encapsulating material wherein the semiconductor chip and a portion of the discrete inductor are within the encapsulating material and wherein a portion of the inductor is exposed.

23. A method for manufacturing a semiconductor component, comprising:
providing a leadframe having a first leadframe lead;
positioning a discrete passive circuit element adjacent the leadframe;
coupling a semiconductor die to the passive circuit element, the semiconductor die having a plurality of bond pads;
electrically coupling the first leadframe lead to a first bond pad of the plurality of bond pads; and
forming a packaging material around a portion of the leadframe, a portion of the discrete passive circuit element, and a portion of the semiconductor die.

24. The method of claim 23, wherein positioning the discrete passive circuit element adjacent the leadframe includes laterally positioning the discrete passive circuit element adjacent the leadframe.

25. The method of claim 23, wherein positioning the discrete passive circuit element adjacent the leadframe includes vertically coupling the discrete passive circuit element to the leadframe using a die attach material.
